(19) United States
(12) Patent Application Publication
(10) Pub. No.: US 2026/0164931 A1
(43) Pub. Date: Jun. 11, 2026

(54) ORGANIC LIGHT EMITTING DEVICE AND METHOD FOR FORMING THE SAME

(71) Applicant: UNI-CHEM SPECIALTY MATERIALS PTE. LTD., SINGAPORE (SG)

(72) Inventors: LING-JUN LIU, CHIAYI CITY (TW); HUI-SHAN HSIEH, HSINCHU COUNTY (TW); WEI-FAN LIN, MIAOLI COUNTY (TW)

(21) Appl. No.: 19/383,746

(22) Filed: Nov. 9, 2025

Related U.S. Application Data
(60) Provisional application No. 63/728,643, filed on Dec. 5, 2024.

(51) Int. Cl. H10K 59/12; H10K 59/122; H10K 59/80

(52) U.S. Cl. CPC H10K 59/1201; H10K 59/122; H10K 59/80515

(57) ABSTRACT

An organic light emitting device and a method for forming an organic light emitting device are provided. The method includes forming a lower electrode over a substrate; forming an organic material layer over the lower electrode; exposing the organic material layer to a light absorbent to form an organic residue region on the organic material layer; forming an emitting layer over the organic residue region; and forming an upper electrode over the emitting layer.

### BACKGROUND OF THE PRESENT DISCLOSURE

### Field of the Present Disclosure

The present disclosure relates to an organic light emitting device and a method for forming an organic light emitting device.

### Description of the Prior Art

Currently, organic light emitting diode (OLED) devices are made by forming light emitting layers by evaporation deposition with a fine metal mask (FMM). However, the resolution of the FMM is relatively poor, which adversely affects the display performance of the OLED devices.

### SUMMARY OF THE PRESENT DISCLOSURE

In some embodiments, a method for forming an organic light emitting device includes forming a lower electrode over a substrate; forming an organic material layer over the lower electrode; exposing the organic material layer to a light absorbent to form an organic residue region on the organic material layer; forming an emitting layer over the organic residue region; and forming an upper electrode over the emitting layer.

In some embodiments, an organic light emitting device includes a first lower electrode over a substrate; a first organic light emitting layer over the first lower electrode; and an organic residue region on at least a portion of the first organic light emitting layer, wherein the organic residue region comprises a carbonyl group, a —C—O group, a phenyl group, an aromatic hydrogen, an alkyl group, an alkyne group, a monofluoromethyl group, a trifluoromethyl group, a —S═O group, a —C—S group, a —CH₃ group, a —O—H group, a —P═O group, an aromatic —C═C group, a —C—O—C group, a —C—F group, a —C—F₃ group, a —C≡C group, a —N—H group, a NO₂ group, a —C═N⁺ group, a —N—O group, a PF₆ group, or a combination thereof.

In some embodiments, an organic light emitting device includes a first electrode, a second electrode, an isolation structure, and an organic light emitting layer. The first electrode and the second electrode are disposed over a top surface of a substrate. The isolation structure is disposed over the substrate and spaces the first electrode apart from the second electrode. The organic light emitting layer extends over the first electrode, the second electrode, and the isolation structure. The isolation structure has a top surface substantially aligned with a top surface of the first electrode, or the isolation structure has a lateral surface inclined at an angle of less than about 80°relative to the top surface of the substrate.

### BRIEF DESCRIPTION OF THE DRAWINGS

FIG. 1A to FIG. 1C illustrate various steps of a method for forming an organic light emitting device according to some embodiments.

FIG. 2A to FIG. 2L illustrate various steps of a method for forming an organic light emitting device according to some embodiments.

FIG. 3A to FIG. 3F illustrate various steps of a method for forming an organic light emitting device according to some embodiments.

FIG. 3G illustrates various steps of a method for forming an organic light emitting device according to some embodiments.

FIG. 4A to FIG. 4F illustrate various steps of a method for forming an organic light emitting device according to some embodiments.

FIG. 5A to FIG. 5H illustrate various steps of a method for forming an organic light emitting device according to some embodiments.

FIG. 6A to FIG. 6B illustrate various steps of a method for forming an organic light emitting device according to some embodiments.

FIG. 7A to FIG. 7F illustrate various steps of a method for forming an organic light emitting device according to some embodiments.

FIG. 8A to FIG. 8B illustrate various steps of a method for forming an organic light emitting device according to some embodiments.

### DETAILED DESCRIPTION OF THE EMBODIMENTS

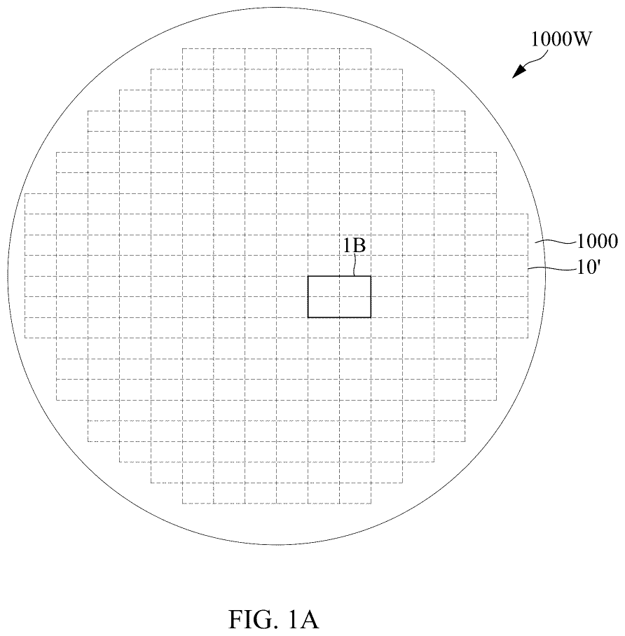

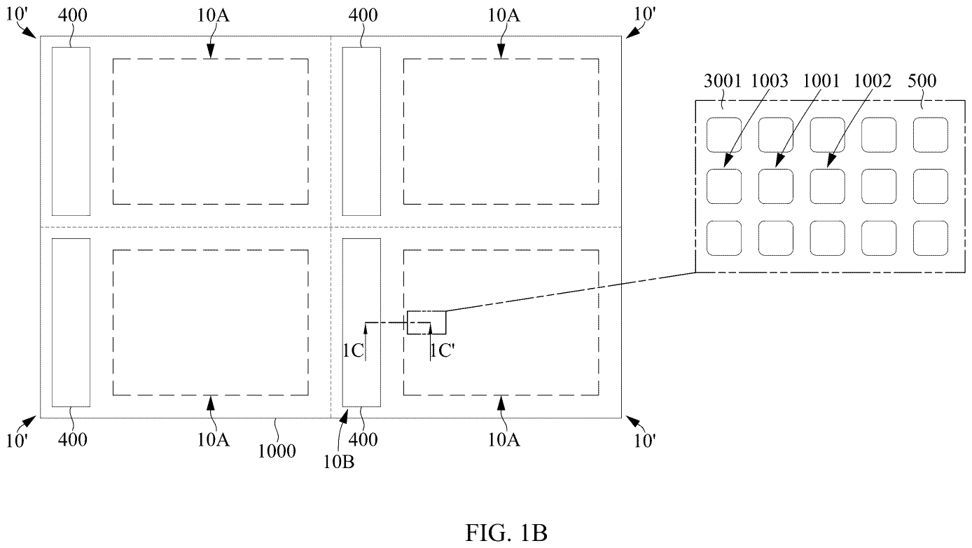

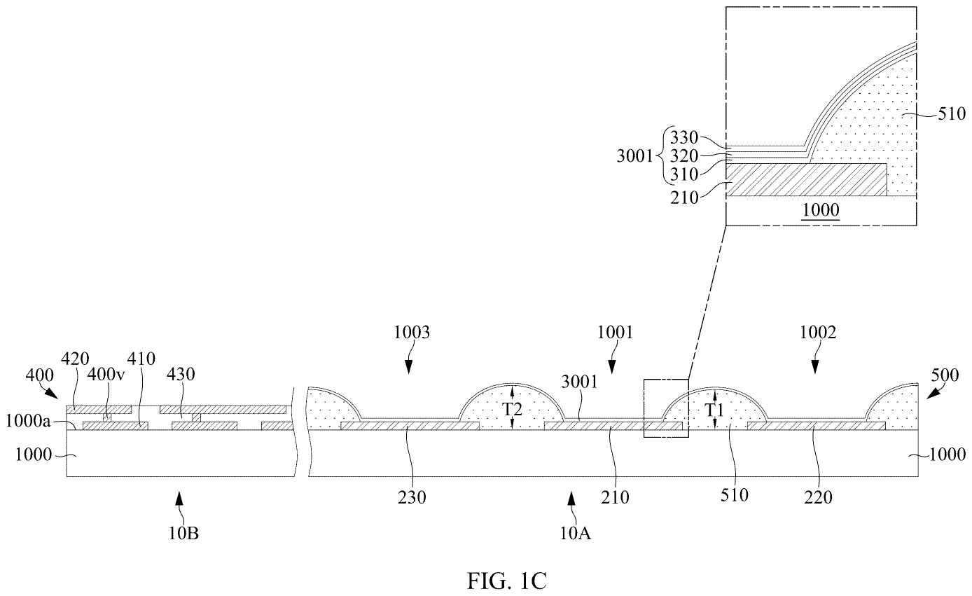

FIG. 1A to FIG. 1C illustrate various steps of a method for forming an organic light emitting device 10 according to some embodiments. The organic light emitting device 10 may be or include an organic light emitting diode (OLED) device. In some embodiments, FIG. 1A shows a top view of an intermediate structure during one or more steps of the method for forming the organic light emitting device 10, FIG. 1B shows a top view of a portion 1B of the intermediate structure shown in FIG. 1A, and FIG. 1C shows a cross-section along a line 1C-1C′ in FIG. 1B. Please be noted that some elements are omitted in FIG. 1A and FIG. 1B for brevity and clarity.

Referring to FIG. 1A, a wafer-level structure 1000W including a substrate 1000 having or defining a plurality of device regions 10′ and a non-display region 10B around the device regions 10′ may be provided. The substrate 1000 may be a wafer. The substrate 1000 may be or include a semiconductor wafer or a glass plate.

Referring to FIG. 1B, each of the device regions 10′ of the substrate 1000 may have or define a display region 10A, and the display regions 10A may be surrounded by the non-display region 10B. In some embodiments, each of the device regions 10′ includes a circuit structure 400, and the circuit structures 400 are formed on the non-display region 10B. The circuit structure 400 may include a plurality of transistors. The circuit structure 400 may further include capacitors or any applicable electronic elements. The circuit structure 400 may be configured to electrically couple to an organic light emitting element (which will be formed subsequently) of the display region 10A. The circuit structure 400 may further include an interconnection structure electrically connected to the transistors and/or the capacitors and additional applicable electronic elements.

Referring to FIG. 1C, the circuit structures 400 may be formed by the following operations. In some embodiments, the substrate 1000 is covered by a buffer layer (not shown in drawings) with portions of a surface 1000a of the substrate 1000 exposed by the buffer layer, transistors and/or applicable electronic elements (not shown in drawings) may be formed on or partially in the substrate 1000, patterned conductive layers 410 are formed on the exposed portions of the surface 1000a to electrically connect to the transistors and/or the applicable electronic elements, conductive vias 400v are formed on and electrically connected to the patterned conductive layers 410, patterned conductive layers 420 are formed on and electrically connected to the conductive vias 400v, and dielectric structures 430 are formed to cover the patterned conductive layers 410 and 420 and the conductive vias 400v on the portions of the surface 1000a, so as to form the circuit structures 400 on the portions of the surface 1000a exposed by the buffer layer. The buffer layer may then be removed after the circuit structures 400 are formed to expose the display regions 10A. In some embodiments, on each of the portions exposed by the buffer layer, a first dielectric layer may be formed on the patterned conductive layer 410 and the conductive vias 400v with top surfaces of the conductive vias 400v exposed by the first dielectric layer, the patterned conductive layer 420 is then formed on the first dielectric layer and the exposed conductive vias 400v, and a second dielectric layer may be formed on the first dielectric layer with the patterned conductive layer 420 exposed by the second dielectric layer. As such, the first dielectric layer and the second dielectric layer may collectively form the dielectric structure 430, the patterned conductive layers 410 and 420 and the conductive vias 400v may collectively form the interconnection structure of the circuit structure 400, and the circuit structure 400 on each of the portions of the surface 1000a of the substrate 1000 exposed by the buffer layer may be formed.

Referring to FIG. 1B and FIG. 1C, electrodes 210, 220, and 230 (also referred to as “lower electrodes”) may be formed over each of the display regions 10A of the substrate 1000, a protrusion structure 500 may be formed over each of the display regions 10A of the substrate 1000 and partially covering the electrodes 210, 220, and 230, and an organic material layer 3001 may be formed over each of the protrusion structures 500 and the electrodes 210, 220, and 230 over each of the display regions 10A. In some embodiments, each of the display regions 10A of the substrate 1000 includes a plurality of regions 1001, 1002, and 1003 (also referred to as “pixel regions” or “sub-pixel regions”) defined by the protrusion structure 500. The protrusion structure 500 may be referred to as an isolation structure that spaces the electrodes 210, 220, and 230 apart from one another.

Referring to FIG. 1C, in some embodiments, the electrodes 210, 220, and 230 are formed on the regions 1001, 1002, and 1003, respectively, and spaced apart from one another by the protrusion structure 500. The electrodes 210, 220, and 230 may be anodes. The electrodes 210, 220, and 230 may be formed by deposition, sputtering, or any suitable process. The electrodes 210, 220, and 230 may be formed of or include one or more metal materials, e.g., Ag, Al, Mg, Au, indium tin oxide (ITO), indium zinc oxide (IZO), or any combinations thereof.

Referring to FIG. 1C, in some embodiments, the protrusion structure 500 includes a plurality of protrusions 510 to define a light emitting pixel pattern of the display region 10A. In some embodiments, the protrusion structure 500 serves as a pixel defined layer (PDL). The light emitting pixel pattern may include a plurality of pixel regions or sub-pixel regions (e.g., the regions 1001, 1002, and 1003). Recesses may be located between every two adjacent protrusions 510 and provide spaces for accommodating light emitting pixels. The protrusions 510 are spaced apart from each other in a cross-sectional view perspective as shown in FIG. 1C; however, the protrusions 510 may be connected to one another by other parts of the protrusion structure 500 in a top view perspective as shown in FIG. 1B. The protrusions 510 may be referred to as isolation structures or isolation layers that space the electrodes 210, 220, and 230 apart from one another.

Referring to FIG. 1C, in some embodiments, the protrusions 510 have curved surfaces. In some embodiments, at least two of the protrusions 510 have different thicknesses. For example, the protrusion 510 between the electrodes 210 and 220 has a thickness T1 less than a thickness T2 of the protrusion 510 between the electrodes 210 and 230. The protrusion structure 500 may be formed of or include a dielectric material or an insulating material.

Referring to FIG. 1C, in some embodiments, the organic material layer 3001 includes a carrier injection layer 310, a carrier transport layer 320, and an electron block layer (EBL) 330. The carrier injection layer 310 may be a hole injection layer (HIL), and the carrier transport layer 320 may be a hole transport layer (HTL). In some embodiments, the carrier injection layer 310, the carrier transport layer 320, and the EBL 330 include organic materials. In some embodiments, the carrier injection layer 310, the carrier transport layer 320, and the EBL 330 may be formed by evaporation deposition. In some embodiments, the electrodes 210, 220, and 230, the protrusion structure 500, and the organic material layer 3001 are not formed on the circuit structures 400.

In some embodiments, the circuit structures 400 may be covered by a buffer layer with the display regions 10A exposed, so that the electrodes 210, 220, and 230, the protrusion structure 500, and the organic material layer 3001 are formed on the display regions 10A of the device regions 10′ of the substrate 1000. In some embodiments, the buffer layer that covers the circuit structures 400 is removed after the electrodes 210, 220, and 230, the protrusion structure 500, and the organic material layer 3001 are formed.

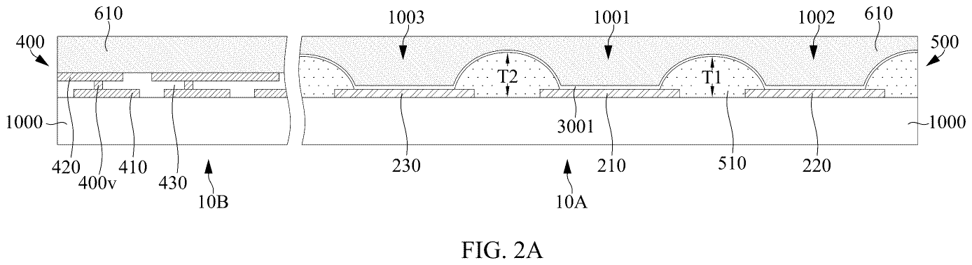

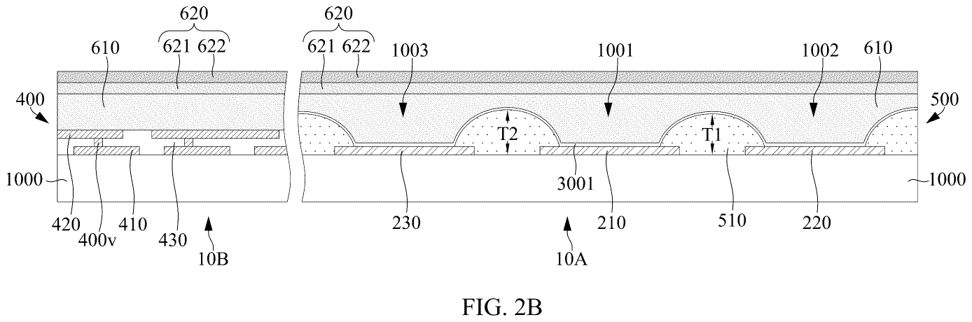

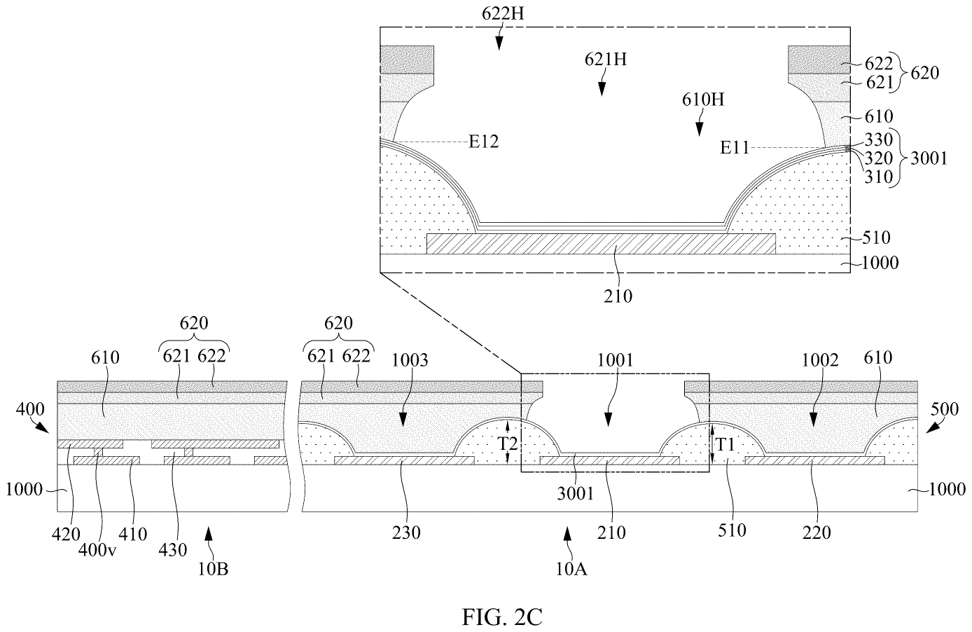

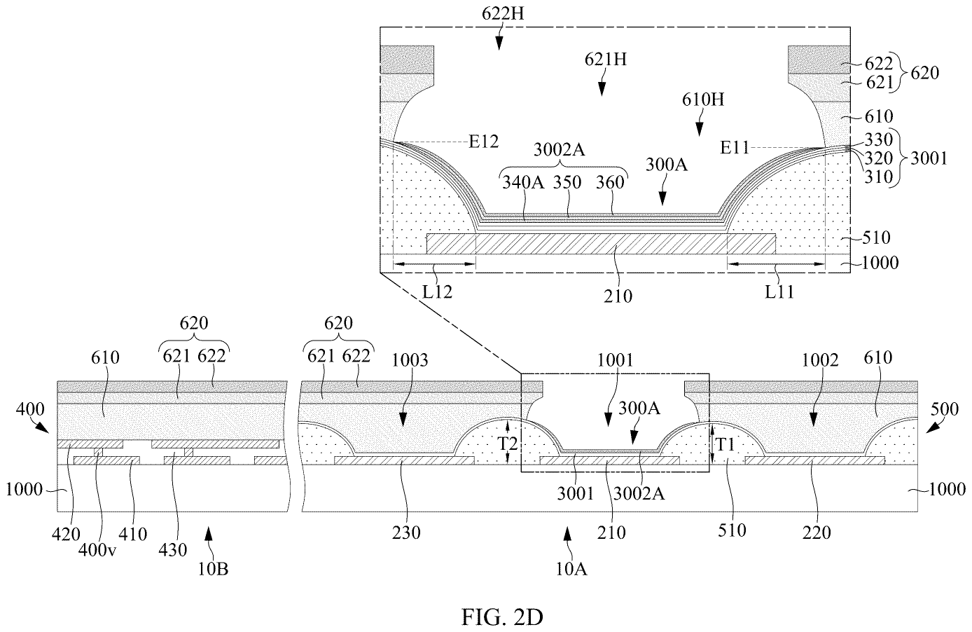

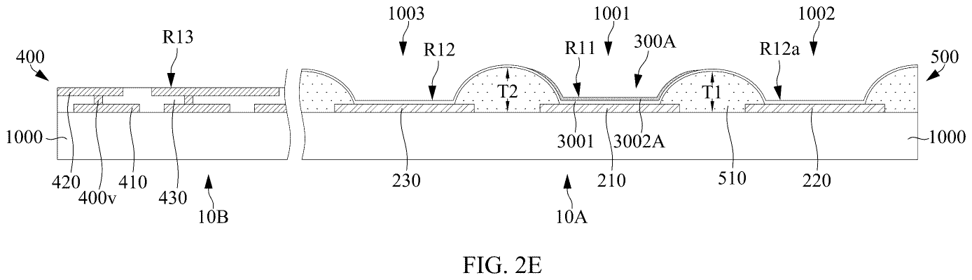

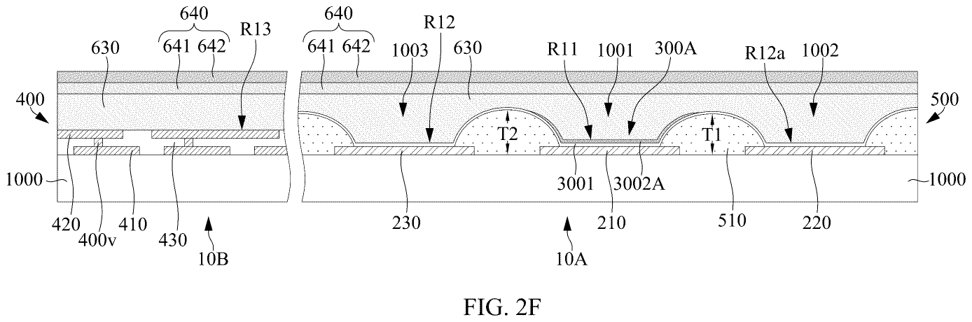

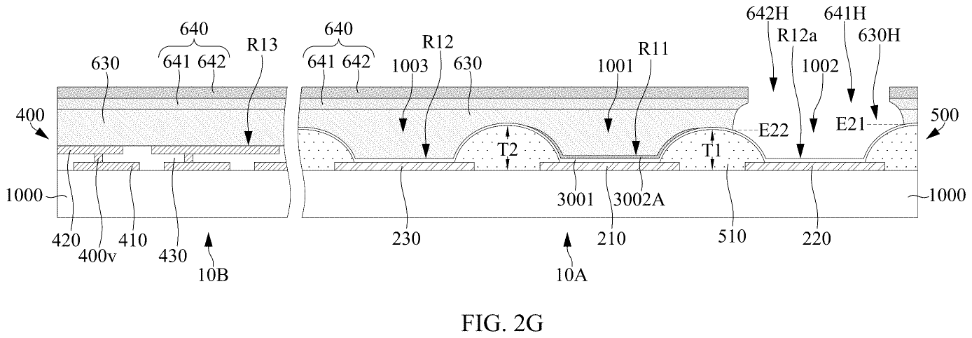

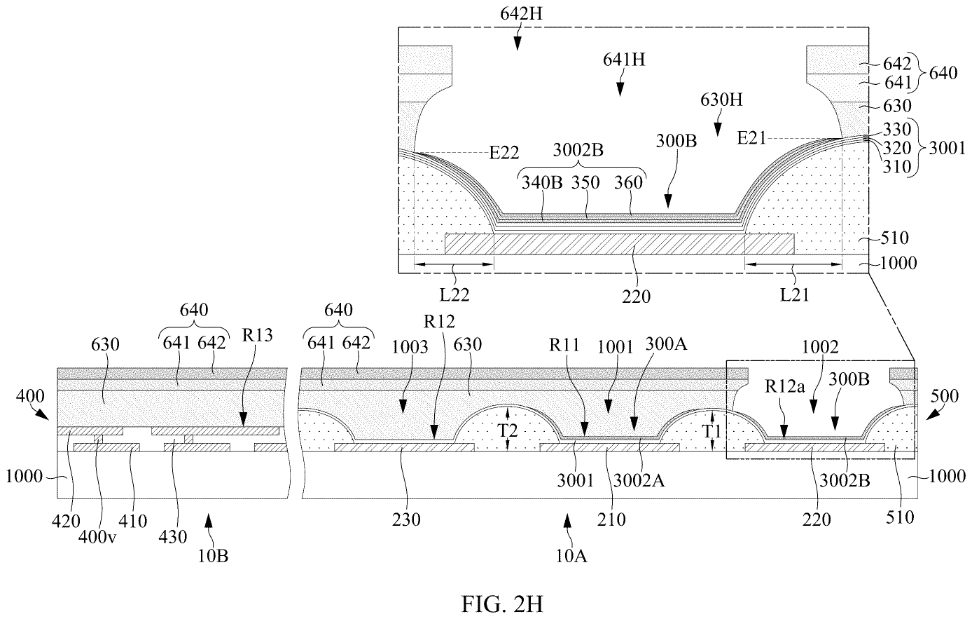

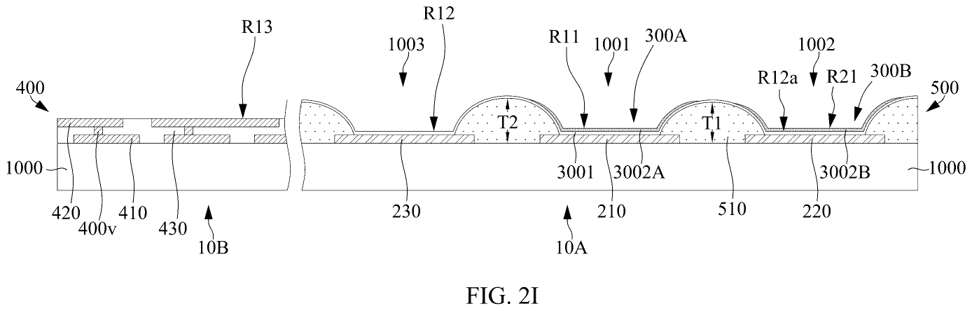

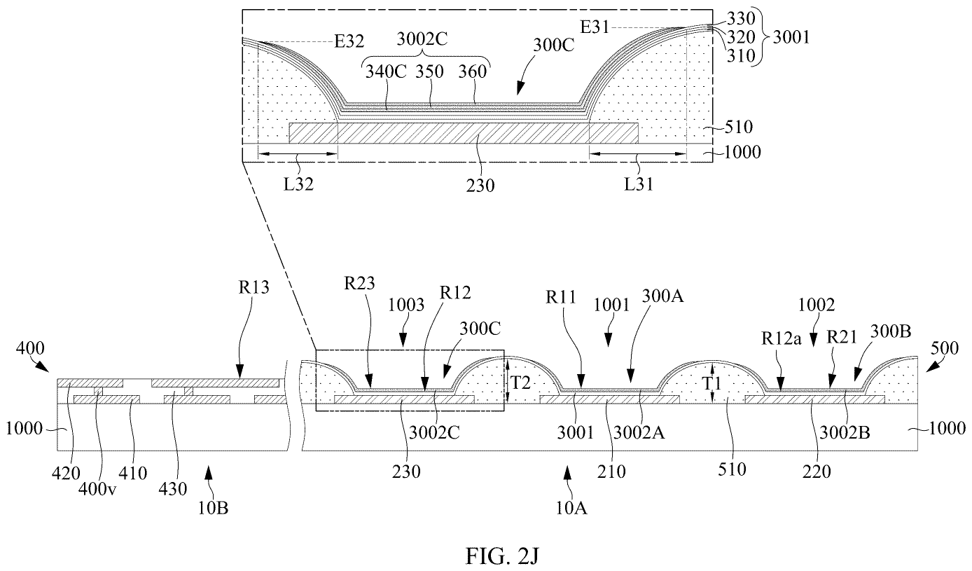

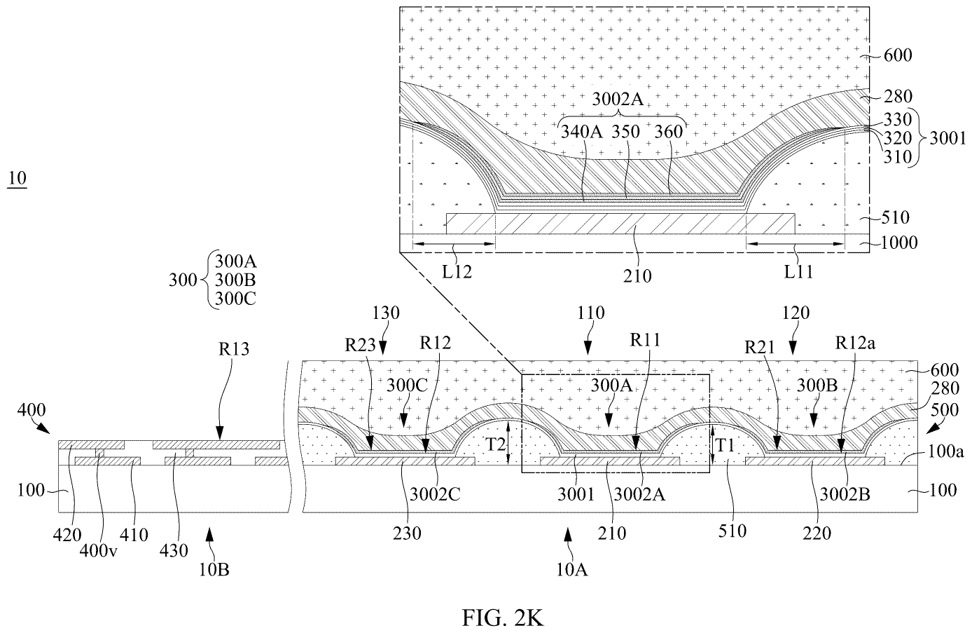

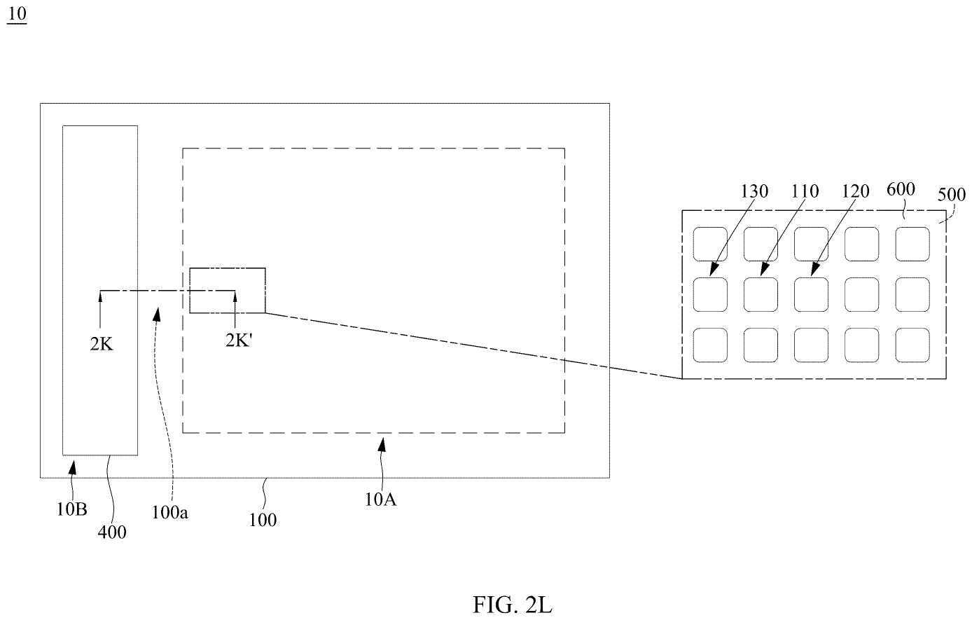

FIG. 2A to FIG. 2K illustrate various steps of a method for forming an organic light emitting device 10 according to some embodiments.

Referring to FIG. 2A, a buffer layer 610 may be formed over the organic material layer 3001. In some embodiments, the buffer layer 610 is formed over the organic material layer 3001 in each of the display regions 10A. In some embodiments, the buffer layer 610 is further formed on the circuit structures 400. In some embodiments, the buffer layer 610 is formed of or includes an organic material or a dielectric material. The buffer layer 610 may be formed by a coating process.

Referring to FIG. 2B, a photoresist structure 620 may be formed over the organic material layer 3001. In some embodiments, the photoresist structure 620 is formed over the buffer layer 610 in each of the display regions 10A. In some embodiments, the photoresist structure 620 includes a light absorbent. The light absorbent allows a lithography process to be performed on the photoresist structure 620 utilizing a light having a predetermined wavelength range corresponding to the light absorbent to pattern the photoresist structure 620. The light may be a G-line light (about 436 nm), an H-line light (about 405 nm), and/or an I-line light (about 365 nm). The light absorbent may include one or more organic compounds having a carbonyl group, a phenyl group, a —C—O group, an aromatic hydrogen, an alkyl group, an alkyne group, a monofluoromethyl group, a trifluoromethyl group, a —S═O group, a —C—S group, a —CH₃ group, or a combination thereof. The light absorbent may include one or more organic compounds having an infrared absorption peak at a wavelength of 1680 to 1850 cm⁻¹ (corresponding to a carbonyl group), a wavelength of about 1600 cm⁻¹ (corresponding to a phenyl group), a wavelength of 1250 to 1300 cm⁻¹ (corresponding to a —C—O group), a wavelength of 2100 to 2260 cm⁻¹ (corresponding to an alkyne group), a wavelength of about 1400 cm⁻¹ (corresponding to a monofluoromethyl group), a wavelength of 1100 to 1200 cm⁻¹ (corresponding to a trifluoromethyl group), a wavelength of about 3000 cm⁻¹ (corresponding to an alkyl group), a wavelength exceeding 3000 cm⁻¹ (corresponding to an aromatic hydrogen), a wavelength of 1100 to 1400 cm⁻¹ (corresponding to a —S═O group), a wavelength of 690 to 730 cm⁻¹ (corresponding to a —C—S group), a wavelength of 1350 to 1370 cm⁻¹ (corresponding to a —CH₃ group), or a combination thereof.

In some embodiments, a photoinitiator may be used in the lithography process. In some embodiments, the photoinitiator may include at least one of the following: a type I photoinitiator (cleavage type), a type II photoinitiator (H-abstracting type), an acid-type photoinitiator (photoacid generator, PAG), a base-type photoinitiator (photobase generator, PBG), and a dual-function type (hybrid) photoinitiator. The type I photoinitiator may exhibit prominent IR peaks at around 1715 cm⁻¹ (C═O), 3400 cm⁻¹ (O—H), and 1250 cm⁻¹ (C—O). These compounds generate free radicals directly upon exposure to ultraviolet light, making them suitable for free-radical polymerization in UV adhesives and UV-cured resins. The type I photoinitiator is commonly employed in I-line photoresists. The type II photoinitiator may show characteristic absorptions near 1660 cm⁻¹ (C═O), 1180 cm⁻¹ (P═O), and around 1600 cm⁻¹ (aromatic C═C). The type II photoinitiator is typically used in thick films and coating systems, especially for G-line photoresists. The acid-type photoinitiator may display a complex set of IR bands: carbonyl stretches between 1600 and 1850 cm⁻¹, aromatic C═C vibrations near 1500-1600 cm⁻¹, C—O—C stretches from 1250-1200 cm⁻¹, S═O stretches at 1180-1030 cm⁻¹, and additional features such as C—F (1100-1400 cm⁻¹ ), CF₃ (1200 cm⁻¹), C—S (690-730 cm⁻¹), C≡C (2100-2260 cm⁻¹), and sp³ C—H signals above 3000 cm⁻¹. The acid-type photoinitiator is commonly employed in in both I-line and G-line photoresists. The base-type photoinitiator may be identified by peaks at 3350 cm⁻¹ (N—H), 1730 cm⁻¹ (C═O), nitro-related absorptions at 1530/1350 cm⁻¹, as well as bands for C—O (1240 cm⁻¹), C═N⁺ (1630 cm⁻¹), N—O (1270 cm⁻¹), and PF₆⁻ at 840 cm⁻¹. The base-type photoinitiator may generate basic species that can be employed in some negative photoresists. The dual-function type photoinitiator may include features of type I, type II, and acid-type photoinitiators to create mixed systems and hardened films suitable for I-line photoresist applications.

In some embodiments, forming the photoresist structure 620 includes forming a photoresist layer 621 over the organic material layer 3001 and forming a photoresist layer 622 contacting the photoresist layer 621. In some embodiments, the photoresist layer 621 is formed over and contacting the buffer layer 610. In some embodiments, a light transmittance of the photoresist layer 621 is lower than a light transmittance of the photoresist layer 622. In some embodiments, the photoresist layer 621 includes a photoresist material including a first absorbent material of the light absorbent, and the photoresist layer 622 includes a photoresist material including a second absorbent material of the light absorbent that is different from the first absorbent material. The first absorbent material may include one or more organic compounds having a carbonyl group, a phenyl group, an aromatic hydrogen, an alkyl group, a —S═O group, a —C—S group, a —CH₃ group, or a combination thereof. The second absorbent material may include one or more organic compounds having a carbonyl group, a phenyl group, an alkyl group, an alkyne group, a monofluoromethyl group, a trifluoromethyl group, a —S═O group, a —C—S group, a —CH₃ group, or a combination thereof.

The photoresist layer 621 may be referred to as an adhesion layer and configured to increase an adhesion between the photoresist layer 622 and the organic material layer 3001. The photoresist layer 622 may be configured to define an exposed portion of the organic material layer 3001. In some embodiments, the photoresist structure 620 may include one or more photoresist layers in addition to the photoresist layers 621 and 622. The multiple photoresist layers may further protect the underlying organic material layer 3001 from damages by the subsequent lithography processes.

Referring to FIG. 2C, one or more lithography processes may be performed on the photoresist structure 620 to define one or more openings (e.g., openings 621H and 622H), and a portion of the buffer layer 610 may be removed to form an opening 610H that exposes a portion of the organic material layer 3001. In some embodiments, the buffer layer 610 is partially removed according to a pattern of the photoresist structure 620 to partially expose the organic material layer 3001 over the electrode 210. In some embodiments, the photoresist layers 621 and 622 are partially removed to form openings 621H and 622H, and the opening 610H is formed directly under the openings 621H and 622H. In some embodiments, due to the different compositions of the photoresist layers 621 and 622, the openings 621H and 622H have different profiles. The opening 621H may be larger than the opening 622H, and the opening 610H may be larger than the opening 621H. Due to an alignment shift when performing the lithography process, the openings 621H and 622H may be shifted from the electrode 210, and thus edges E11 and E12 of the exposed portion of the organic material layer 3001 are at different elevations. In some embodiments, a G-line light (with a wavelength about 436 nm) is utilized to perform the lithography process on the photoresist structure 620, and the light absorbent in the photoresist structure 620 includes one or more organic compounds having a —S═O group, a —C—S group, a —CH₃ group, or a combination thereof is configured to react with the G-line light. The G-line light has a relatively reduced intensity compared to an H-line light or an I-line light, such that the damages caused by the lithography process can be reduced, which is advantageous to the yield and the reliability of the organic light emitting device.

Referring to FIG. 2D, an organic material layer 3002A may be formed over a portion of the organic material layer 3001 exposed by the buffer layer 610 and over the electrode 210. In some embodiments, an emitting layer (EL) 340A may be formed over the portion of the organic material layer 3001 exposed by the buffer layer 610 and over the electrode 210. In some embodiments, an electron transport layer (ETL) 350 is formed on the EL 340A, and an electron injection layer (EIL) 360 is formed on the ETL 350. In some embodiments, the EL 340A, the ETL 350, and the EIL 360 include organic materials. In some embodiments, the EL 340A, the ETL 350, and the EIL 360 may be formed by evaporation deposition. In some embodiments, the EL 340A, the ETL 350, and the EIL 360 may be collectively referred to as the organic material layer 3002A. In some embodiments, the organic material layer 3002A extends over the protrusions 510 at opposite sides by different lengths L11 and L12. A portion of the organic material layer 3001 over the electrode 210 and the organic material layer 3002A may be collectively referred to as an organic light emitting layer 300A.

Referring to FIG. 2E, the buffer layer 610 and the photoresist structure 620 may be removed. In some embodiments, a solution is applied to remove the photoresist layer 621 (or the adhesion layer) and the photoresist layer 622 and bring the light absorbent that is dissolved in the solution to contact the exposed portion of the organic material layer 3001 and the organic material layer 3002A. In some embodiments, the exposed portion of the organic material layer 3001 and the organic material layer 3002A are exposed to the light absorbent to form a portion R11 of an organic residue region on the organic material layer 3002A and portions R12 and R12a of the organic residue region on the exposed portion of the organic material layer 3001. In some embodiments, the circuit structure 400 of the substrate 1000 is exposed to the light absorbent dissolved in the solution to form a portion R13 of the organic residue region further on the circuit structure 400. In some embodiments, the organic residue region includes a carbonyl group, a phenyl group, a —C—O group, an aromatic hydrogen, an alkyl group, an alkyne group, a monofluoromethyl group, a trifluoromethyl group, a —S═O group, a —C—S group, a —CH₃ group, a —O—H group, a —P═O group, an aromatic —C═C group, a —C—O—C group, a —C—F group, a —C—F₃ group, a —C≡C group, a —N—H group, a NO₂ group, a —C═N⁺ group, a —N—O group, a PF₆ group, or a combination thereof.

Referring to FIG. 2F, operations similar to those illustrated in FIG. 2B may be performed to form a buffer layer 630 and a photoresist structure 640 including photoresist layers 641 and 642 over the organic residue region. The buffer layer 630 is the same as or similar to the buffer layer 610, the photoresist structure 640 is the same as or similar to the photoresist structure 620, the photoresist layer 641 is the same as or similar to the photoresist layer 621, the photoresist layer 642 is the same as or similar to the photoresist layer 622, and thus the description thereof are omitted hereinafter.

Referring to FIG. 2G, operations similar to those illustrated in FIG. 2C may be performed to partially remove the buffer layer 630 and the photoresist structure 640 to form openings 630H, 641H, and 642H. Due to an alignment shift when performing the lithography process, the openings 641H and 642H may be shifted from the electrode 220, and thus edges E21 and E22 of the exposed portion of the organic material layer 3001 are at different elevations.

Referring to FIG. 2H, operations similar to those illustrated in FIG. 2D may be performed to form an organic material layer 3002B including an emitting layer 340B over the organic residue region (the exposed portion R12a). In some embodiments, the organic material layer 3002B extends over the protrusions 510 at opposite sides by different lengths L21 and L22. A portion of the organic material layer 3001 over the electrode 220 and the organic material layer 3002B may be collectively referred to as an organic light emitting layer 300B.

Referring to FIG. 2I, operations similar to those illustrated in FIG. 2E may be performed to remove the buffer layer 630 and the photoresist structure 640. In some embodiments, a solution is applied to remove the photoresist layer 641 (or the adhesion layer) and the photoresist layer 642 and bring the light absorbent from the photoresist structure 640 that is dissolved in the solution to contact the exposed portion of the organic material layer 3001 and the organic material layers 3002A and 3002B. In some embodiments, the organic material layer 3002B is exposed to the light absorbent to form a portion R21 of an organic residue region on the organic material layer 3002B. In some embodiments, more organic residues are formed on the portions R11, R12, and R13 of the organic residue region.

Referring to FIG. 2J, operations similar to those illustrated in FIG. 2B to FIG. 2E may be performed to form an organic material layer 3000C including an emitting layer 340C over the organic residue region (the exposed portion R13). Due to an alignment shift when performing the lithography process for forming openings above the electrode 230, edges E31 and E32 of the organic material layer 3002C are at different elevations. In some embodiments, the organic material layer 3002C extends over the protrusions 510 at opposite sides by different lengths L31 and L32. A portion of the organic material layer 3001 over the electrode 230 and the organic material layer 3002C may be collectively referred to as an organic light emitting layer 300C.

In some embodiments, a solution is applied to remove photoresist layers and bring the light absorbent that is dissolved in the solution to contact the organic material layers 3002A, 3002B, and 3002C. In some embodiments, the organic material layer 3002C is exposed to the light absorbent to form a portion R23 of an organic residue region on the organic material layer 3002C. In some embodiments, more organic residues are formed on the portions R11, R13, and R21 of the organic residue region.

Referring to FIG. 2K and FIG. 2L, an electrode 280 (also referred to as “an upper electrode”) may be formed over a light emitting layer 300 including the organic light emitting layers 300A, 300B, and 300C. The organic light emitting layers 300A, 300B, and 300C are configured to emit lights having different colors. The electrode 280 may be a cathode. In some embodiments, the electrode 280 is a common electrode of all light emitting pixels in the light emitting layer 300. The electrode 280 may be formed by deposition, sputtering, or any suitable process. The electrode 280 may be formed of or include one or more metal materials, e.g., Ag, Al, Mg, Au, ITO, IZO, or any combinations thereof.

Next, referring to FIG. 2K and FIG. 2L, a cap layer 600 may be formed over the electrode 280, and a singulation operation may be performed on the substrate 1000 to divide it into a plurality of organic light emitting devices 10 each corresponds to a device region 10′. As such, an organic light emitting device 10 as shown in FIG. 2K and FIG. 2L may be formed.

Referring to FIG. 2K and FIG. 2L, FIG. 2L shows a top view of the organic light emitting device 10, and FIG. 2K shows a cross-section along a line 2K-2K′ in FIG. 2K. The organic light emitting device 10 may include a substrate 100, organic light emitting elements 110, 120, and 130, a protrusion structure 500 (also referred to as “isolation layer”), a cap layer 600, and an organic residue region. The organic residue region may be referred to as a light absorbent exposure region. In some embodiments, the organic light emitting element 110 includes an electrode 210, an organic light emitting layer 300A, and an electrode 280, the organic light emitting element 120 includes an electrode 220, an organic light emitting layer 300B, and an electrode 280, and the organic light emitting element 130 includes an electrode 230, an organic light emitting layer 300C, and an electrode 280. In some embodiments, the substrate 100 further includes a circuit structure 400 spaced apart from the organic light emitting elements 110, 120, and 130.

In some embodiments, the electrodes 210, 220, and 230 are over a surface 100a of the substrate 100, and the organic light emitting layers 300A, 300B, and 300C are over the electrodes 210, 220, and 230, respectively. In some embodiments, the organic residue region is on at least a portion of the organic light emitting layers 300A, 300B, and/or 300C. In some embodiments, the organic residue region includes portions R11, R12, R12a, R21, and R23 within the organic light emitting layers 300A, 300B, and/or 300C. In some embodiments, the various portions of the organic residue region may be located at interfaces between two adjacent organic materials layers of one or more of the organic light emitting layers 300A, 300B, and 300C. In some embodiments, the various portions of the organic residue region may diffuse or extend into one or more portions of one or more organic materials layers of one or more of the organic light emitting layers 300A, 300B, and 300C. In some embodiments, the organic residue region further includes a portion R13 on the circuit structure 400. In some embodiments, the organic residue region further includes a portion that is on a portion of the surface 100a of the substrate 100 between the circuit structure 400 and the organic light emitting elements 110, 120, and 130.

In some embodiments, different portions of the organic residue region may have different concentration of the organic residues. In some embodiments, a concentration of the portion R13 is higher than a concentration of the portion R11 of the organic residue region, which is higher than concentrations of the portions R12 and R12a of the organic residue region.

In some embodiments, the organic residue region includes one or more organic residues having a carbonyl group, a phenyl group, a —C—O group, an aromatic hydrogen, an alkyl group, an alkyne group, a monofluoromethyl group, a trifluoromethyl group, a —S═O group, a —C—S group, a —CH₃ group, a —O—H group, a —P═O group, an aromatic —C═C group, a —C—O—C group, a —C—F group, a —C—F₃ group, a —C≡C group, a —N—H group, a NO₂ group, a —C═N⁺ group, a —N—O group, a PF₆ group, or a combination thereof. In some embodiments, the organic residue region includes one or more organic residues having an infrared absorption peak at a wavelength of 1680 to 1850 cm⁻¹ (corresponding to a carbonyl group), a wavelength of about 1600 cm⁻¹ (corresponding to a phenyl group), a wavelength of 1250 to 1300 cm⁻¹ (corresponding to a-C-O group), a wavelength of 2100 to 2260 cm⁻¹ (corresponding to an alkyne group), a wavelength of about 1400 cm⁻¹ (corresponding to a monofluoromethyl group), a wavelength of 1100 to 1200 cm⁻¹ (corresponding to a trifluoromethyl group), a wavelength of about 3000 cm⁻¹ (corresponding to an alkyl group), a wavelength exceeding 3000 cm⁻¹ (corresponding to an aromatic hydrogen), a wavelength around 1715 cm⁻¹ (C═O), a wavelength of about 3400 cm⁻¹ (O—H), a wavelength of about 1250 cm⁻¹ (C—O), a wavelength near 1660 cm⁻¹ (C═O), a wavelength of about 1180 cm⁻¹ (P═O), a wavelength around 1600 cm⁻¹ (aromatic C═C), a wavelength between 1600 and 1850 cm⁻¹ (carbonyl stretches), a wavelength near 1500-1600 cm⁻¹ (aromatic C═C vibrations), a wavelength from 1250-1200 cm⁻¹ (C—O—C stretches), a wavelength at 1180-1030 cm⁻¹ (S═O stretches), a wavelength of 1100-1400 cm⁻¹ (C—F), CF₃ (1200 cm⁻¹), a wavelength of 690-730 cm⁻¹ (C—S), a wavelength of 2100-2260 cm⁻¹ (C≡C), a wavelength above 3000 cm⁻¹ (sp³ C—H), a wavelength of about 3350 cm⁻¹ (N—H), a wavelength of about 1730 cm⁻¹ (C═O), a wavelength of about 1530/1350 cm⁻¹ (nitro-related absorptions), a wavelength of about 1240 cm⁻¹ (C—O), a wavelength of about 1630 cm⁻¹ (C═N⁺), a wavelength of about 1270 cm⁻¹ (N—O), a wavelength of about 840 cm⁻¹ (PF₆⁻) , or a combination thereof.

According to some embodiments of the present disclosure, photoresist layers are used to define the openings of the buffer layers that correspond to pixel regions of the organic light emitting device. Compared to defining patterns of organic light emitting layers using FMMs, the resolution of the organic light emitting device 10 can be increased significantly.

In addition, according to some embodiments of the present disclosure, two photoresist layers are used instead of only one photoresist layer to define the opening of the buffer layer for defining pixel regions of the organic light emitting device. For example, the photoresist layers 621 and 622 include similar materials and thus are highly compatible and can be adhered to each other stably. In addition, the photoresist layer 622 includes organic materials having an alkyne group, a monofluoromethyl group, a trifluoromethyl group, or a combination thereof, which are advantageous to provide or define patterns having a relatively high resolution, and the photoresist layer 621 that is substantially free of the above materials can increase the adhesion between the photoresist layer 622 and the underlying layer (e.g., the organic material layer 3001) so as to lower the risk of delamination.

Moreover, according to some embodiments of the present disclosure, the photoresist structure 620 includes multiple photoresist layers instead of only one photoresist layer, such that the multi-layered structure can further protect the underlying organic material layer 3001 from damages by the subsequent lithography processes.

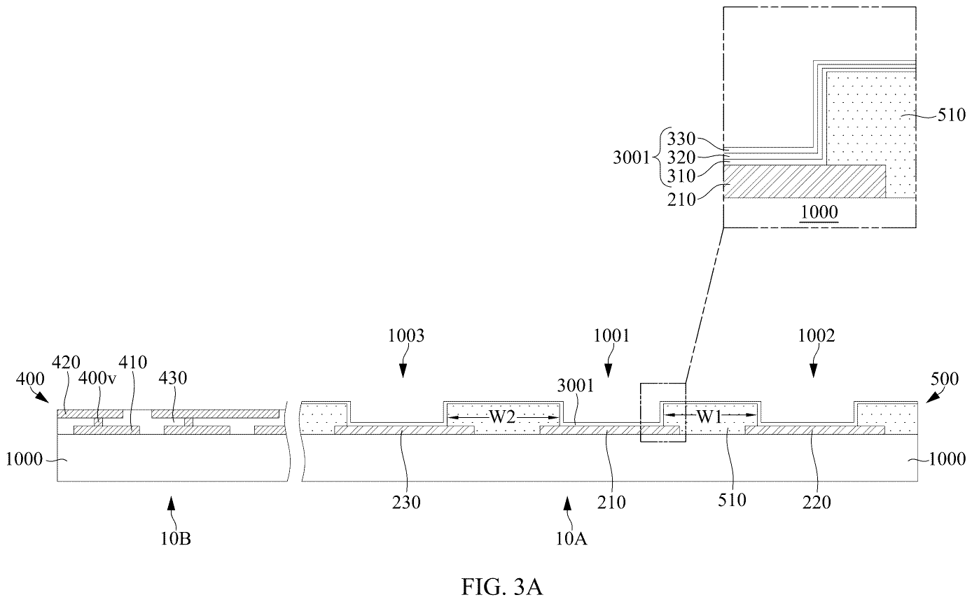

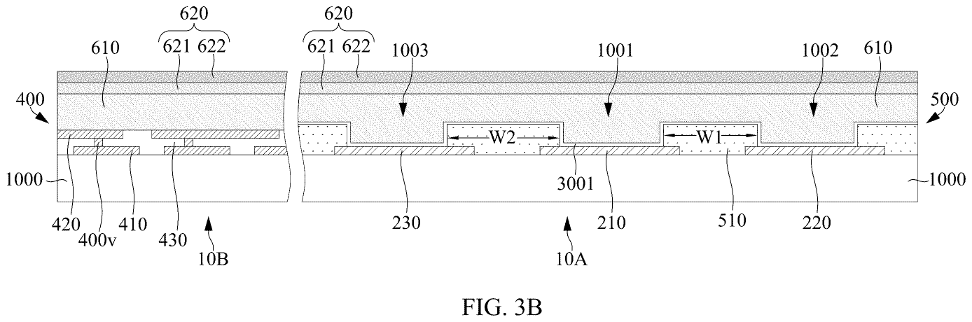

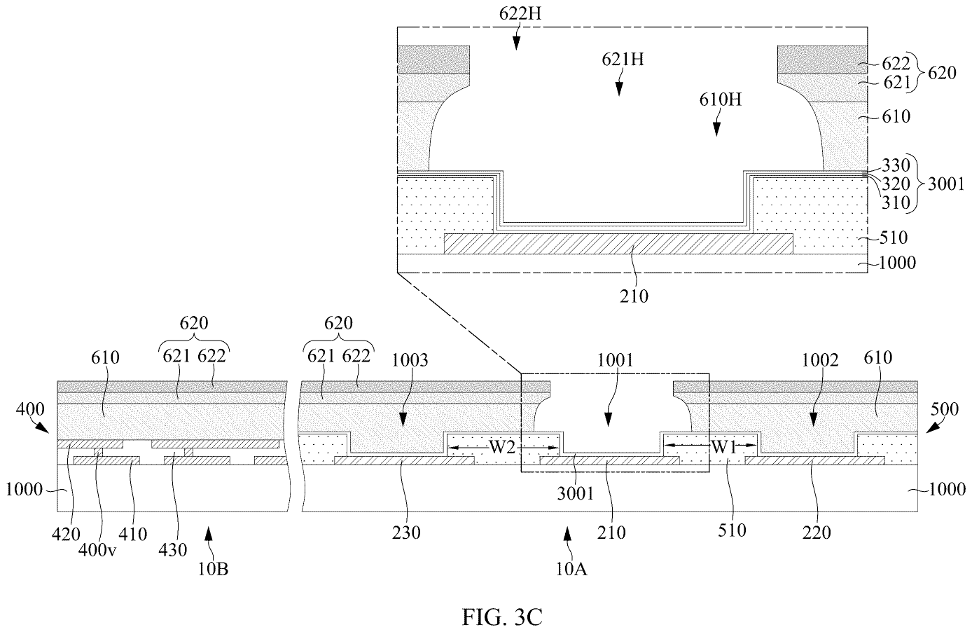

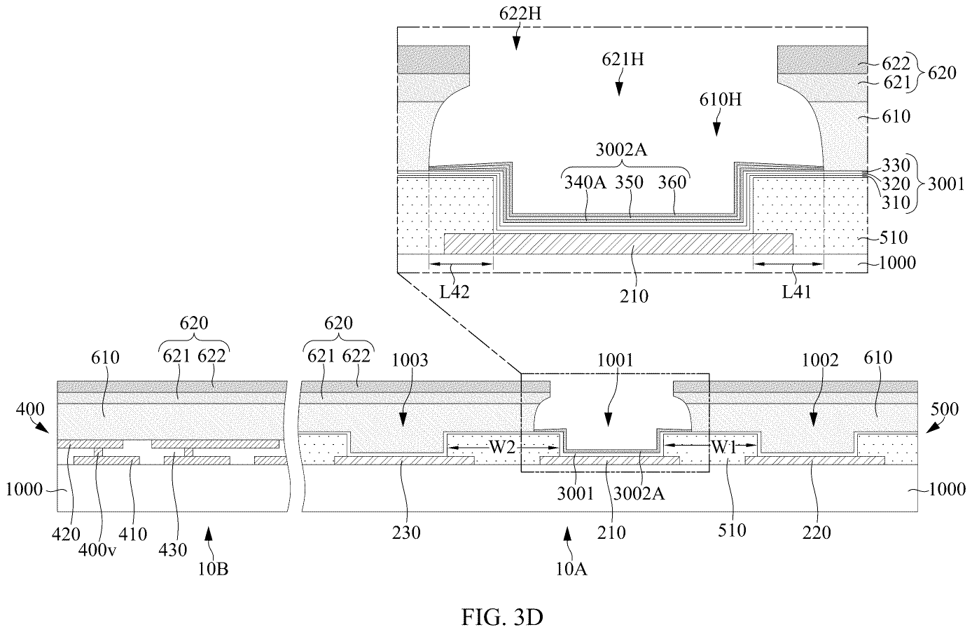

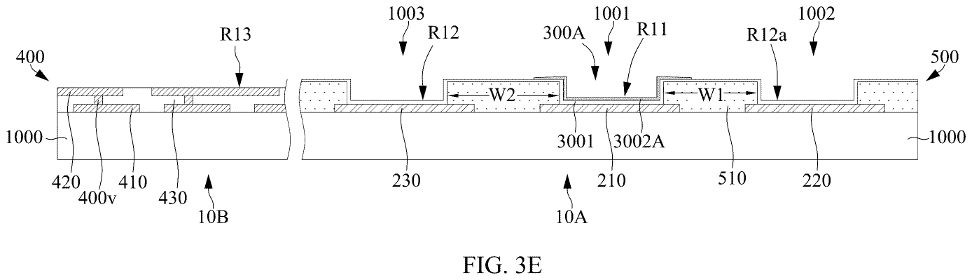

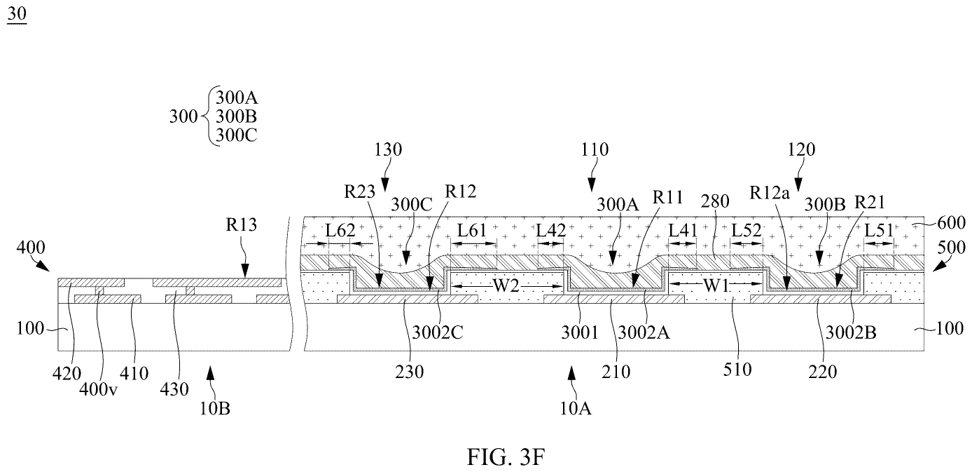

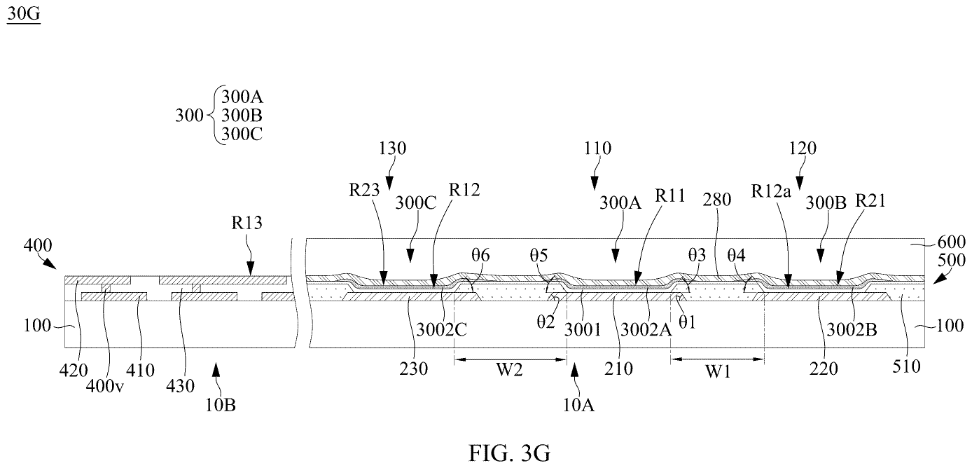

FIG. 3A to FIG. 3F illustrate various steps of a method for forming an organic light emitting device 30 according to some embodiments.

Referring to FIG. 3A, operations similar to those illustrated in FIG. 1A to FIG. 1C may be performed to form electrodes 210, 220, 230, circuit structures 400, and protrusion structures 500 over a substrate 1000, and an organic material layer 3001 over the electrodes 210, 220, 230 and the protrusion structures 500. The protrusion structure 500 includes protrusions 510 having rectangular cross-sectional profiles. At least two of the protrusions 510 may have different widths. For example, the protrusion 510 between the electrodes 210 and 220 has a width W1 less than a width W2 of the protrusion 510 between the electrodes 210 and 230.

Referring to FIG. 3B, operations similar to those illustrated in FIG. 2A and FIG. 2B may be performed to form a buffer layer 610 and a photoresist structure 620 over the organic material layer 3001.

Referring to FIG. 3C, operations similar to those illustrated in FIG. 2C may be performed to partially remove the buffer layer 610 and the photoresist structure 620 to form openings 610H, 621H, and 622H.

Referring to FIG. 3D, operations similar to those illustrated in FIG. 2D may be performed to form an organic material layer 3002A over a portion of the organic material layer 3001 exposed by the buffer layer 610 and over the electrode 210. In some embodiments, the organic material layer 3002A extends over the protrusions 510 at opposite sides by different lengths L41 and L42. In some embodiments, the organic material layer 3002A includes portions over the protrusions 510 at opposite sides and tapering towards opposite directions.

Referring to FIG. 3E, operations similar to those illustrated in FIG. 2E may be performed to remove the buffer layer 610 and the photoresist structure 620, and an organic residue region including portions R11, R12, R12a, and R13 is formed.

Referring to FIG. 3F, operations similar to those illustrated in FIG. 2F to FIG. 2K may be performed to form the organic light emitting device 30. The organic light emitting device 30 is similar to the organic light emitting device 10 illustrated in FIG. 2K and FIG. 2L, except that the protrusions 510 have rectangular cross-sectional profiles. In some embodiments, the organic material layer 3002B extends over the protrusions 510 at opposite sides by different lengths L51 and L52. In some embodiments, the organic material layer 3002C extends over the protrusions 510 at opposite sides by different lengths L61 and L62.

FIG. 3G illustrates various steps of a method for forming an organic light emitting device 30G according to some embodiments.

Referring to FIG. 3G, operations similar to those illustrated in FIG. 3A to FIG. 3F may be performed to form the organic light emitting device 30G, except that the electrodes 210, 220, and 230 and the protrusions 510 are formed with non-rectangular, wedge-shaped profiles.

In some embodiments, the electrode 210 is defined by a first sidewall that makes an angle θ1 with respect to the substrate plane and a second sidewall that makes an angle θ2, thereby producing a tapered geometry that gradually narrows toward the interior of the protrusions 510. In some embodiments, the electrode 220 is patterned with the same wedge geometry as the electrode 210, such that its sidewalls also define angles θ1 and θ2, which may be identical to or different from those of the electrode 210 depending on the desired current-distribution characteristics. In some embodiments, the electrode 230 follows the identical tapered configuration, again employing sidewall angles θ1 and θ2, which collectively ensure that all three electrodes present a smoothly varying thickness from the outer edges toward the central regions of the electrodes 210, 220, and 230.

Referring to FIG. 3G, in some embodiments, the protrusion 510 is shaped so that its sidewalls taper outward, creating a gradual reduction in thickness from the apex of the protrusion 510 to its base. In some embodiments, the protrusions 510 that extend upward from the planarized surface are fabricated as pyramidal or conical structures whose lateral faces are inclined at angles θ3, θ4, θ5, and θ6 relative to the substrate plane (e.g., the top surface of the substrate), thereby providing a multi-faceted shape that can be tailored to specific optical or electrical requirements. In some embodiments, the taper angles θ3-θ6 are selected such that the overall topography of the combined electrode-protrusion array exhibits a substantially planar surface after the protrusions 510 are formed, which greatly facilitates the subsequent deposition of the organic material layer 3001 and the electrode 280. The described geometry of the electrodes 210, 220, and 230 and the protrusions 510 may be realized by lithography and etching techniques, such as anisotropic reactive-ion etching for the electrodes 210, 220, and 230 and isotropic wet or dry etching for the protrusions 510, followed by a planarization step (e.g., CMP) that leaves the tapered profiles intact while removing excess material. In some embodiments, the angles θ1-θ6 are less than about 80°, 75°, 70°, 65°, 60°, 55°, 50°, 45°, 40°, 35°, or 30°. In some embodiments, the angles θ1-θ6 are about 30° to about 85°, about 60° to about 85°, or about 60° to about 70°.

According to some embodiments of the present disclosure, the gradual thinning of both the electrodes 210, 220, and 230 (via angles θ1 and θ2) and the protrusions 510 (via angles θ3-θ6) minimizes abrupt height steps that could otherwise lead to poor step coverage, film voids, or stress concentrations during later process steps. Therefore, this engineered flatness improves the uniformity of overlying functional/material layers, enhances device reliability, and contributes to higher yield in manufacturing.

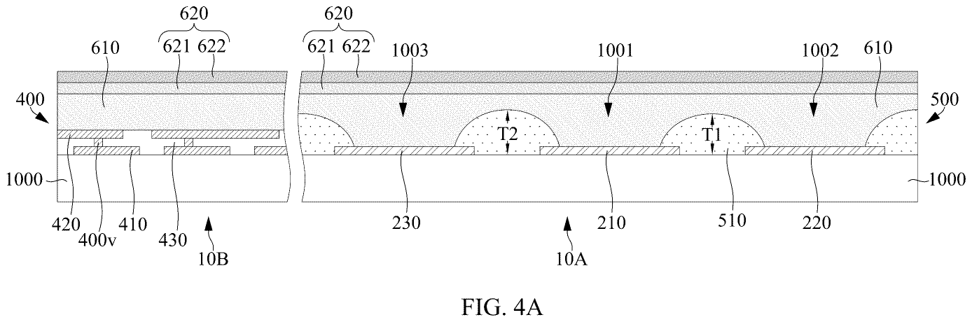

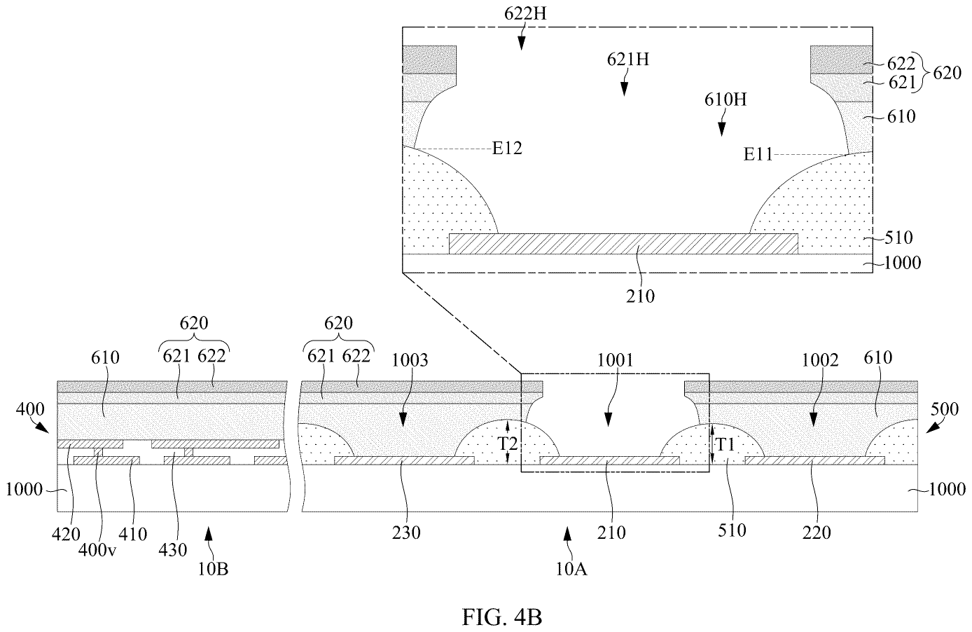

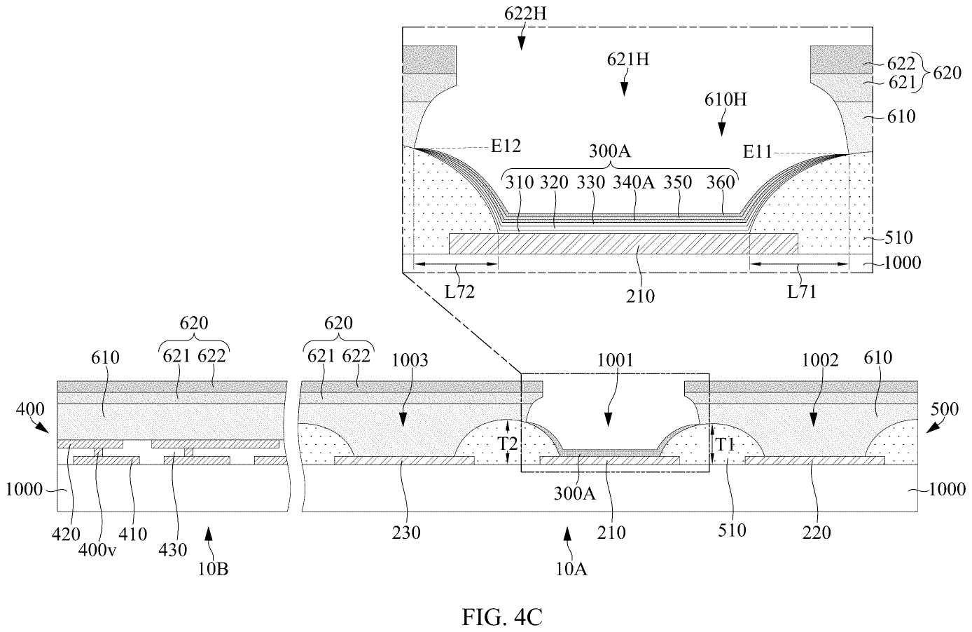

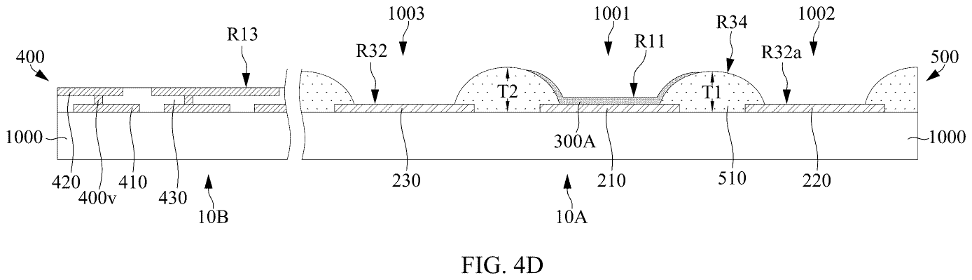

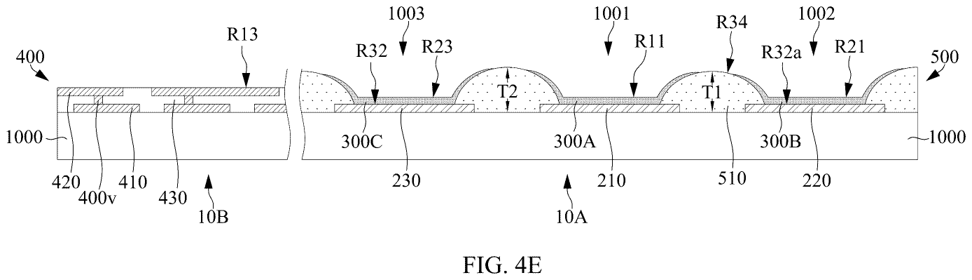

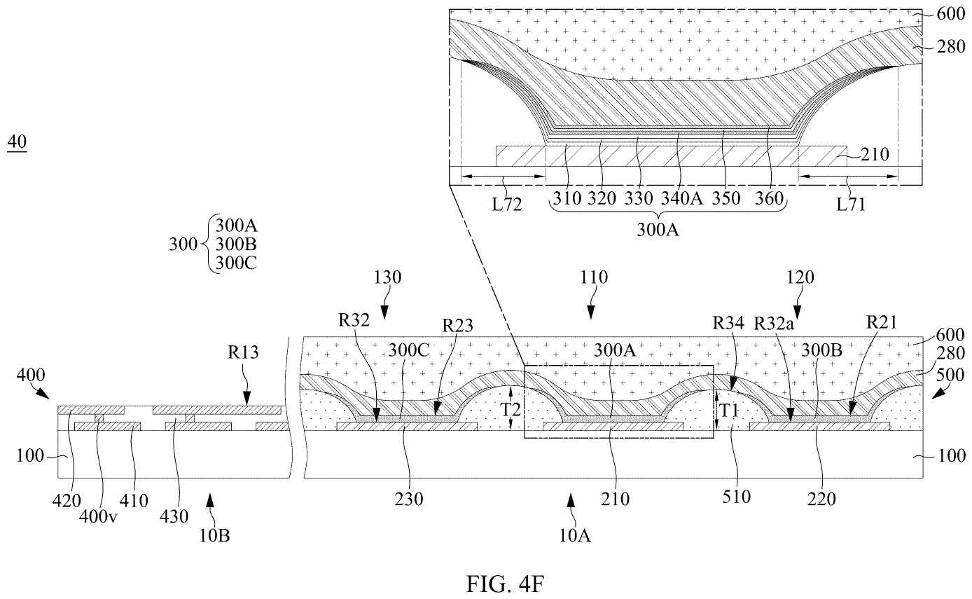

FIG. 4A to FIG. 4F illustrate various steps of a method for forming an organic light emitting device 40 according to some embodiments.

Referring to FIG. 4A, operations similar to those illustrated in FIG. 2A and FIG. 2B may be performed to form a buffer layer 610 and a photoresist structure 620 over the circuit structures 400, the protrusions 510, and the electrodes 210, 220, and 230. In some embodiments, the buffer layer 610 directly contacts the circuit structures 400, the protrusions 510, and the electrodes 210, 220, and 230.

Referring to FIG. 4B, operations similar to those illustrated in FIG. 2C may be performed to partially remove the buffer layer 610 and the photoresist structure 620 to form openings 610H, 621H, and 622H. In some embodiments, portions of the protrusions 510 and a portion of a top surface of the electrode 210 are exposed by the openings 610H, 621H, and 622H.

Referring to FIG. 4C, an organic light emitting layer 300A including a carrier injection layer 310, a carrier transport layer 320, an EBL 330, an EL 340A, an ETL 350, and an EIL 360 may be formed on the portions of the protrusions 510 and the portion of the top surface the electrode 210 exposed by the openings 610H, 621H, and 622H. In some embodiments, the organic light emitting layer 300A extends over the protrusions 510 at opposite sides by different lengths L71 and L72.

Referring to FIG. 4D, the buffer layer 610 and the photoresist structure 620 may be removed. In some embodiments, a solution is applied to remove the photoresist layer 621 (or the adhesion layer) and the photoresist layer 622 and bring the light absorbent that is dissolved in the solution to contact exposed portions of the protrusions 510, exposed portions of top surfaces the electrodes 220 and 230, and the organic light emitting layer 300A. In some embodiments, the exposed portions of the protrusions 510 are exposed to the light absorbent dissolved in the solution to form a portion R34 of an organic residue region on the protrusions 510. In some embodiments, the exposed portions of top surfaces the electrodes 220 and 230 are exposed to the light absorbent dissolved in the solution to form portions R32a and R32 of the organic residue region on the electrodes 220 and 230. In some embodiments, the organic light emitting layer 300A is exposed to the light absorbent dissolved in the solution to form a portion R11 of the organic residue region on the organic light emitting layer 300A. In some embodiments, the circuit structure 400 of the substrate 1000 is exposed to the light absorbent dissolved in the solution to form a portion R13 of the organic residue region further on the circuit structure 400.

Referring to FIG. 4E, operations similar to those illustrated in FIG. 4A to FIG. 4D may be performed to form an organic light emitting layer 300B. In some embodiments, performed, a solution is applied in the lithography process to remove photoresist layers and bring the light absorbent dissolved in the solution to contact exposed portions of the protrusions 510, the exposed portion of the top surfaces the electrode 230, and the organic light emitting layer 300A. In some embodiments, the organic light emitting layer 300B is exposed to the light absorbent to form a portion R21 of the organic residue region on the organic light emitting layer 300B. In some embodiments, more organic residues are formed on the portions R11, R13, R32, and R34 of the organic residue region.

Still referring to FIG. 4E, operations similar to those illustrated in FIG. 4A to FIG. 4D may be performed again to form an organic light emitting layer 300C. In some embodiments, performed, a solution is applied in the lithography process to remove photoresist layers and bring the light absorbent dissolved in the solution to contact exposed portions of the protrusions 510 and the organic light emitting layers 300A and 300B. In some embodiments, the organic light emitting layer 300C is exposed to the light absorbent to form a portion R23 of the organic residue region on the organic light emitting layer 300C. In some embodiments, more organic residues are formed on the portions R11, R13, R21, and R34 of the organic residue region.

In some embodiments, the organic residue region (or the light absorbent exposure region), e.g., the portion R34, is between the electrode 280 and the protrusion structure 500 (or the isolation layer). In some embodiments, a concentration of the organic residue region on the protrusion structure 500 (e.g., the portion R34) is different from a concentration of the organic residue region on the organic material layer (e.g., the organic light emitting layers 300A, 300B, and 300C). In some embodiments, the organic residue region (or the light absorbent exposure region) is among the plurality of organic material layers (e.g., the organic light emitting layers 300A, 300B, and 300C).

Referring to FIG. 4F, operations similar to those illustrated in FIG. 2K may be performed to form the organic light emitting device 40. The organic light emitting device 40 is similar to the organic light emitting device 10 illustrated in FIG. 2K and FIG. 2L, except that the organic residue region at least directly contacts the electrodes 220 and 230 and the protrusion structure 500.

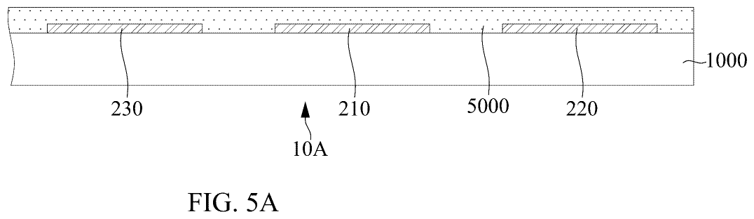

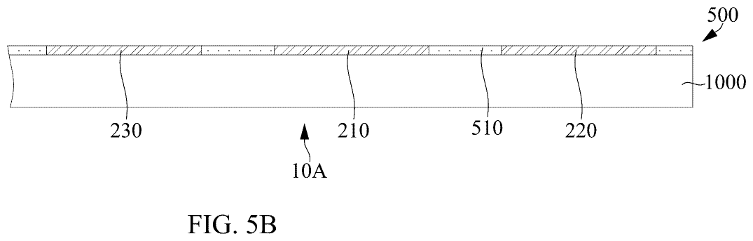

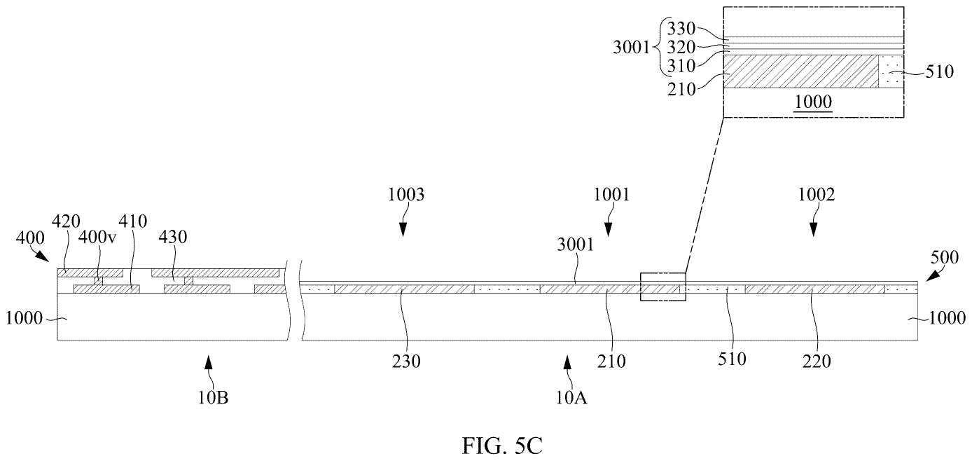

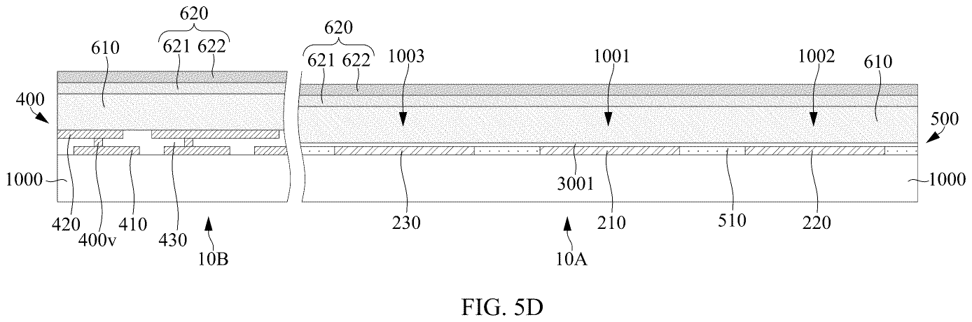

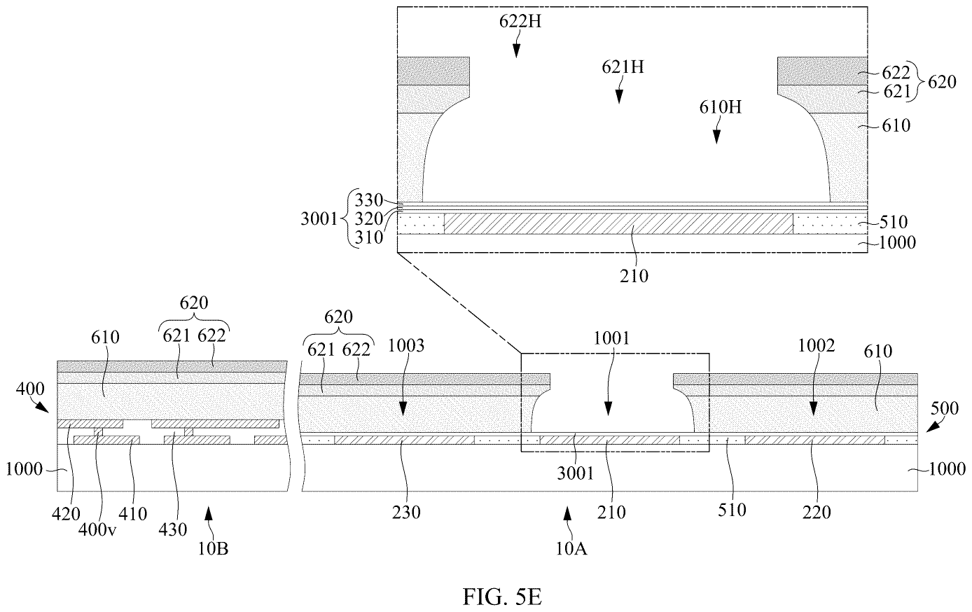

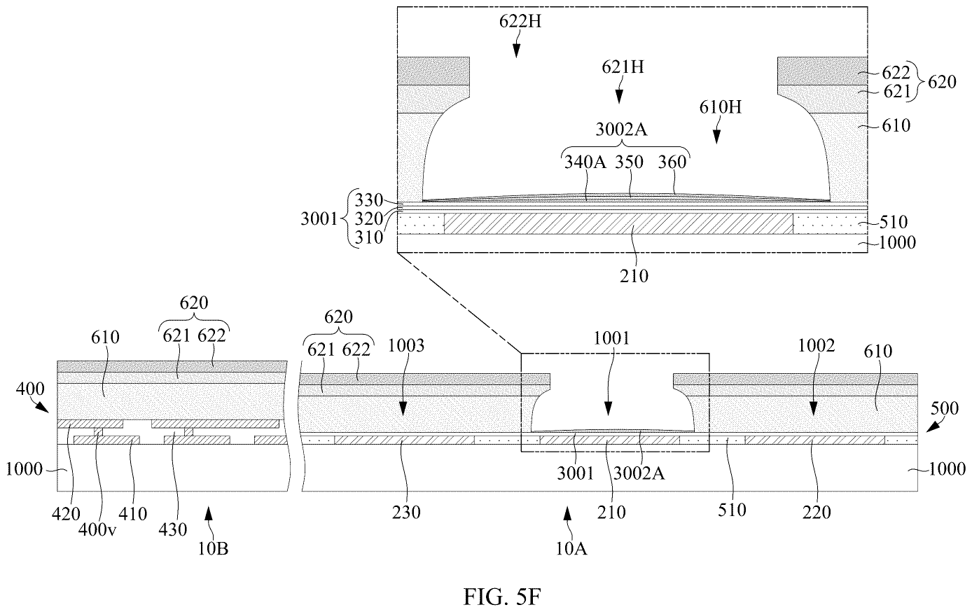

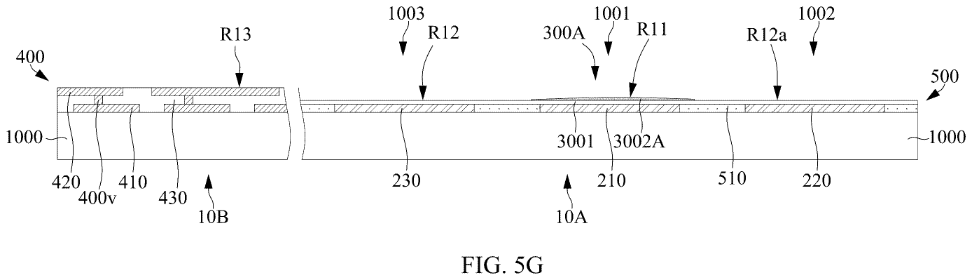

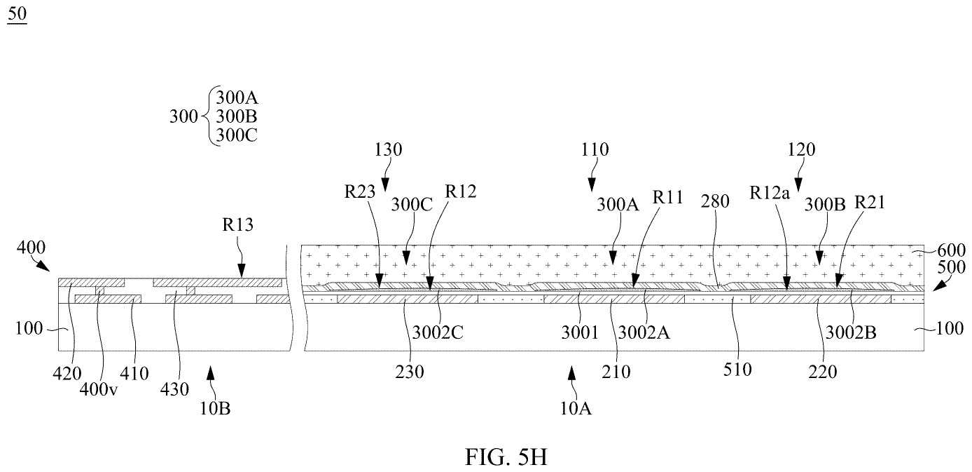

FIG. 5A to FIG. 5H illustrate various steps of a method for forming an organic light emitting device 50 according to some embodiments.

Referring to FIG. 5A, a protrusion structure layer 5000 may be formed over the electrodes 210, 220, and 230 to provide a conformal cover that covers the electrodes 210, 220, and 230. The protrusion structure layer 5000 may be or includes a dielectric or insulating material such as a spin-coated polymer, a cured polyimide, or a sputtered oxide. The protrusion structure layer 5000 may include silicon nitride, silicon oxide, aluminum oxide, or the like.

Referring to FIG. 5B, a planarization process may be performed on the protrusion structure layer 5000 to form a protrusion structure 500. The planarization process may be or include a chemical mechanical planarization (CMP) or a spin-on-planarization (SOP) step. The planarization process removes surface irregularities and selectively removes an upper portion of the protrusion structure layer 5000 until the underlying electrodes 210, 220, and 230 are exposed. The as-formed protrusion structure 500 has a flat top surface while still covering the electrode sides.

Referring to FIG. 5C, an organic material layer 3001 may be formed over the planarized surface. Because the planarization process has exposed the top surfaces of the electrodes 210, 220, and 230 as well as the top surface of the protrusion structure 500, the deposition of the organic material layer 3001 (which may be performed by evaporation, spin-coating, or ink-jet printing) yields a continuous layer that simultaneously contacts the top surfaces of the electrodes 210, 220, and 230 and the protrusion structure 500. This configuration ensures robust electrical contact, minimizes step height, and facilitates subsequent patterning of the organic light emitting layers.

Referring to FIG. 5D, operations similar to those illustrated in FIG. 2A and FIG. 2B may be performed to form a buffer layer 610 and a photoresist structure 620 over the organic material layer 3001.

Referring to FIG. 5E, operations similar to those illustrated in FIG. 2C may be performed to partially remove the buffer layer 610 and the photoresist structure 620 to form openings 610H, 621H, and 622H.

Referring to FIG. 5F, operations similar to those illustrated in FIG. 2D may be performed to form an organic material layer 3002A over a portion of the organic material layer 3001 exposed by the buffer layer 610 and over the electrode 210.

Referring to FIG. 5G, operations similar to those illustrated in FIG. 2E may be performed to remove the buffer layer 610 and the photoresist structure 620, and an organic residue region including portions R11, R12, R12a, and R13 is formed.

Referring to FIG. 5H, operations similar to those illustrated in FIG. 2F to FIG. 2K may be performed to form the organic light emitting device 50. The organic light emitting device 50 is similar to the organic light emitting device 10 illustrated in FIG. 2K and FIG. 2L, except that the top surfaces of the electrodes 210, 220, and 230 as well as the top surface of the protrusion structure 500 generate a substantially flat surface. According to some embodiments of the present disclosure, the substantially flat surface minimizes abrupt height steps that could otherwise lead to poor step coverage, film voids, or stress concentrations during later process steps. Therefore, this engineered flatness improves the uniformity of overlying functional/material layers, enhances device reliability, and contributes to higher yield in manufacturing.

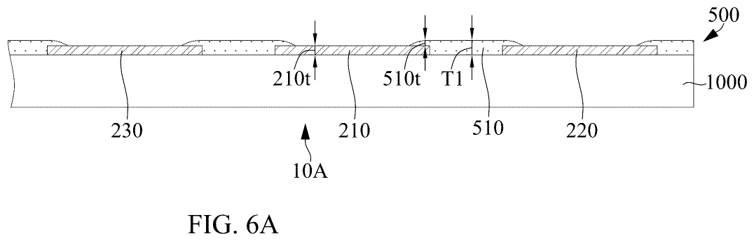

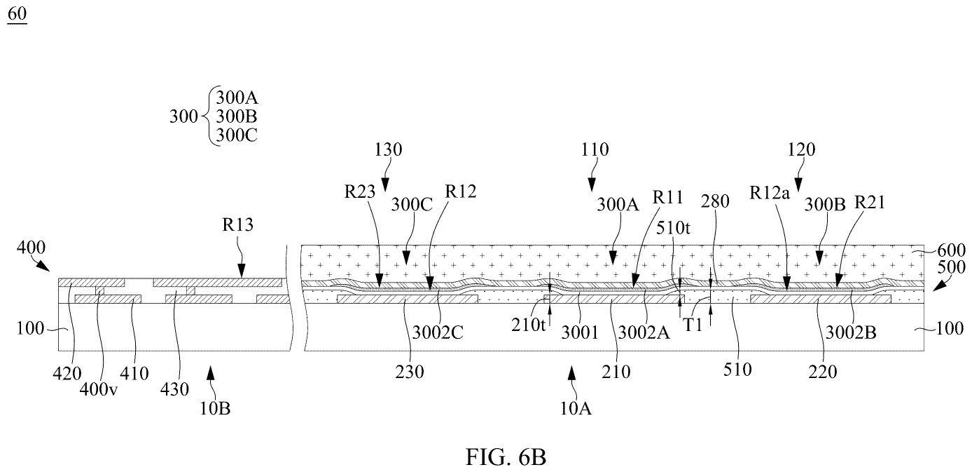

FIG. 6A to FIG. 6B illustrate various steps of a method for forming an organic light emitting device 60 according to some embodiments.

Referring to FIG. 6A, protrusions 510 may be formed to partially cover the electrodes 210, 220, and 230. In some embodiments, the protrusions 510 include edges that extend laterally onto the electrodes 210, 220, and 230 and gradually taper (i.e., “thin”). In some embodiments, a thickness 510t of the edge of the protrusion 510 is greater than a thickness T1 of the main portion of the protrusion 510 and a thickness 210t of the electrode 210. In some embodiments, a protrusion structure layer is formed to cover the electrodes 210, 220, and 230, a planarization process (e.g., CMP or spin-on-planarization) is performed on protrusion structure layer, but the process is intentionally stopped before the electrodes 210, 220, and 230 are fully exposed, thereby leaving a thin residual portion of the protrusion structure layer that remains on the top surfaces of electrodes 210, 220, and 230. Next, in some embodiments, a photoresist pattern is formed on the planarized surface to define the regions where the thin protrusion structure layer will be removed, and then the structure is subjected to a lithography and etching step that selectively removes the exposed portions of the thin protrusion structure layer, thereby exposing selected areas of electrodes 210, 220, and 230 by the as-formed protrusions 510.

Referring to FIG. 6B, operations similar to those illustrated in FIG. 5C to FIG. 5H may be performed to form the organic light emitting device 60.

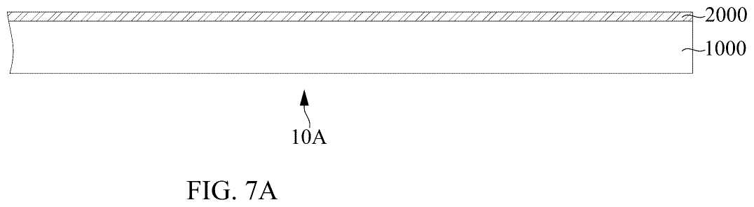

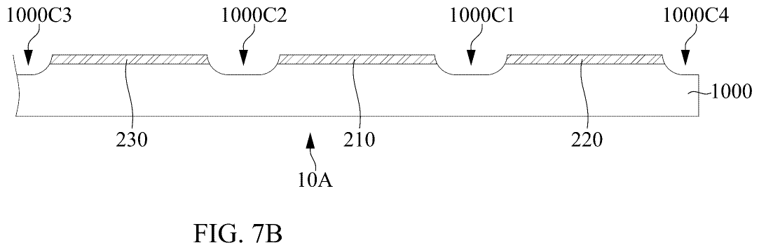

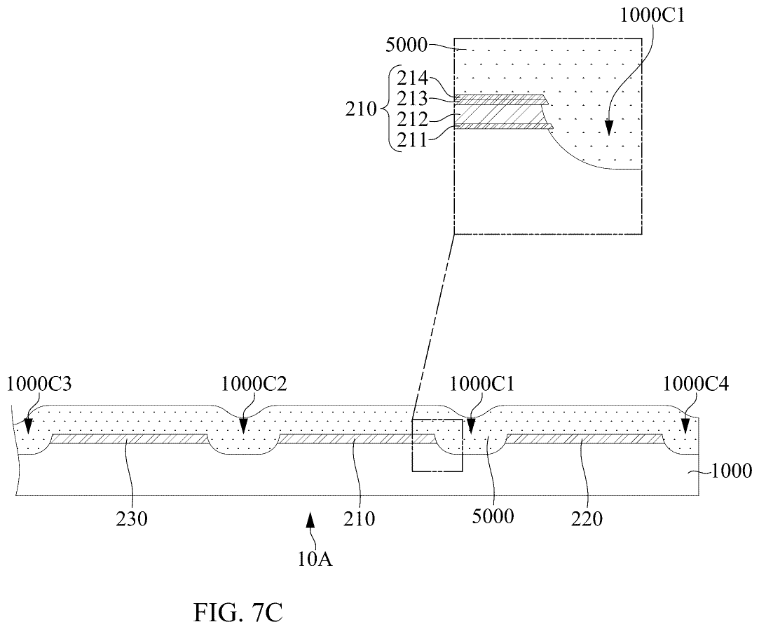

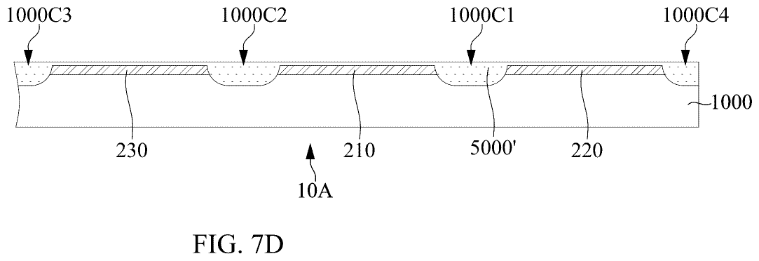

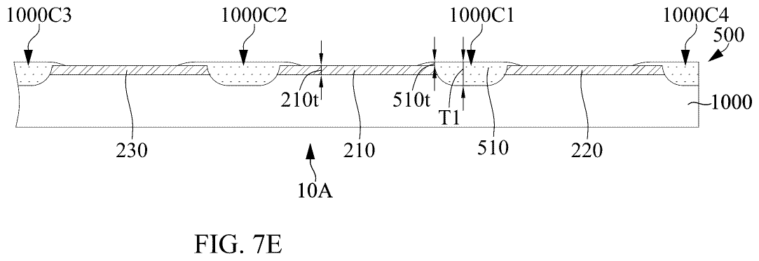

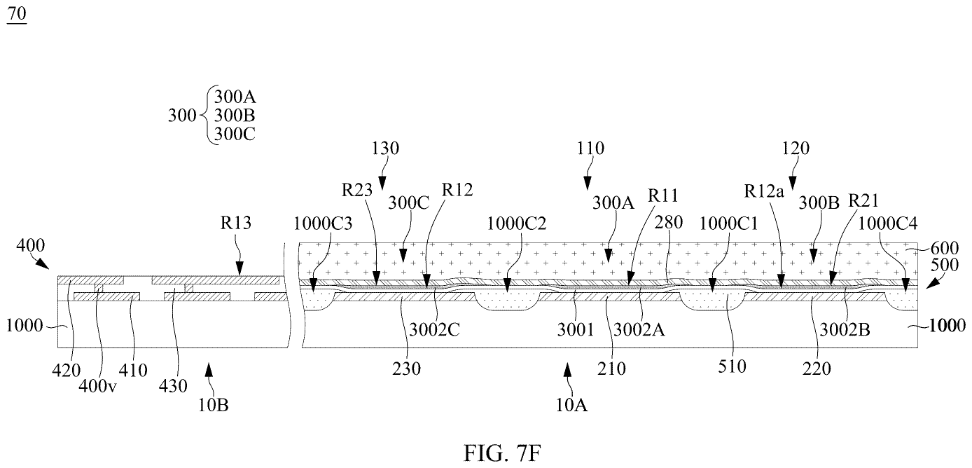

FIG. 7A to FIG. 7F illustrate various steps of a method for forming an organic light emitting device 70 according to some embodiments.

Referring to FIG. 7A, a continuous electrode material layer 2000 is formed over the substrate 1000 so that the electrode material layer 2000 completely blankets the underlying substrate 1000.

Referring to FIG. 7B, electrodes 210, 220, and 230 may be formed, and cavities 1000C1, 1000C2, 1000C3, and 1000C4 may be formed within the substrate 1000. In some embodiments, a photolithographic pattern is transferred into the electrode material layer 2000, and the exposed portions are removed by an anisotropic etch, thereby patterning the electrode material layer 2000 into the individual electrodes 210, 220, and 230. In some embodiments, the electrodes 210, 220, and 230 are spaced apart from one another by the cavities 1000C1, 1000C2, 1000C3, and 1000C4. In some embodiments, the same etch that defines the electrodes 210, 220, and 230 is continued into the underlying substrate 1000, producing a series of cavities 1000C1, 1000C2, 1000C3, and 1000C4 within the substrate 1000.

Referring to FIG. 7C, a conformal protrusion structure layer 5000 may be formed so that it coats the sidewalls and bottoms of cavities 1000C1, 1000C2, 1000C3, and 1000C4 as well as the entire surfaces of electrodes 210, 220, and 230. In some embodiments, the electrode 210 includes sub-layers 211, 212, 213, and 214. The sub-layers may include Al, TiN, AlCu, AlNd, ITO, or the like, or any combination thereof. In some embodiments, the electrode 210 including a stack of the sub-layers 211, 212, 213, and 214 in which some sub-layers protrude outward while others are recessed due to differences in etch selectivity, thereby giving electrode 210 a non-uniform topography.

Referring to FIG. 7D, a planarization step (e.g., CMP or spin-on-planarization) may be performed on the protrusion structure layer 5000, but the planarization step may be intentionally terminated before the electrodes 210, 220, and 230 are fully uncovered, leaving a protrusion structure layer 5000′ with a thin residual coating that remains on the top surfaces of electrodes 210, 220, and 230.

Referring to FIG. 7E, a photoresist pattern may be formed on the planarized surface to expose selected regions of the protrusion structure layer 5000′, and then the structure is subjected to a lithography and etching step that selectively removes the exposed portions of the thin protrusion structure layer 5000′, thereby exposing selected areas of electrodes 210, 220, and 230 by the as-formed protrusions 510 of the protrusion structure 500. In some embodiments, the protrusion structure 500 (or the protrusions 510) may be at least partially within the cavities 1000C1, 1000C2, 1000C3, and 1000C4.

Referring to FIG. 7F, operations similar to those illustrated in FIG. 5C to FIG. 5H may be performed to form the organic light emitting device 70.

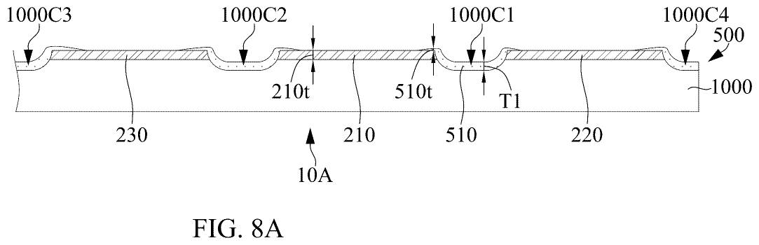

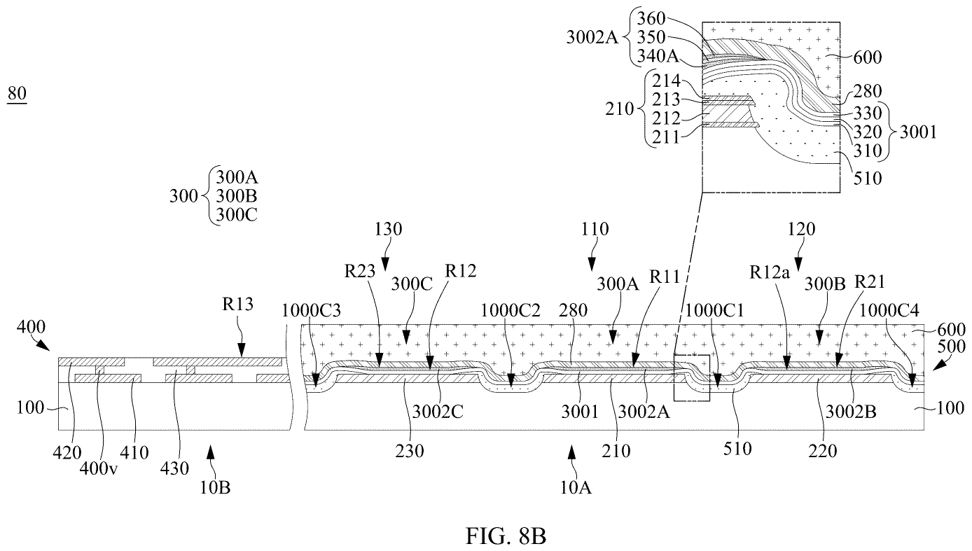

FIG. 8A to FIG. 8B illustrate various steps of a method for forming an organic light emitting device 80 according to some embodiments.

Referring to FIG. 8A, operation similar to those illustrated in FIG. 7A to FIG. 7B may be performed to form cavities 1000C1, 1000C2, 1000C3, and 1000C4 within the substrate 1000 and electrodes 210, 220, and 230 over the substrate 1000. Next, a conformal protrusion structure layer may be formed to coat the top surfaces of electrodes 210, 220, and 230 and also lines the sidewalls of cavities 1000C1, 1000C2, 1000C3, and 1000C4, but the thickness of protrusion structure layer is intentionally limited such that the cavities 1000C1, 1000C2, 1000C3, and 1000C4 are not completely filled. In some embodiments, a thickness of the protrusions 510 of the protrusion structure 500 is less than a depth of the cavities 1000C1, 1000C2, 1000C3, and 1000C4. In some embodiments, no planarization step is performed, and the as-formed protrusion structure layer therefore remains on the electrode tops as a relatively thin film. Next, in some embodiments, a photoresist pattern may be formed on the protrusion structure layer to expose selected regions of the protrusion structure layer, and then the structure is subjected to a lithography and etching step that selectively removes the exposed portions of the protrusion structure layer to form protrusions 510, thereby exposing selected areas of electrodes 210, 220, and 230 by the as-formed protrusions 510. In some embodiments, a thickness 510t of the edge of the protrusion 510 is greater than a thickness T1 of the main portion of the protrusion 510 and a thickness 210t of the electrode 210.

Referring to FIG. 8B, operations similar to those illustrated in FIG. 5C to FIG. 5H may be performed to form the organic light emitting device 80.

The features of some embodiments are given in brief in the description above for a person skilled in the art to better understand various aspects of the present disclosure. A person skilled in the art would be able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the disclosure of the present application, and various changes, substitutions and replacements may be made by a person skilled in the art without departing from the spirit and scope of the present disclosure.

What is claimed is:

1. A method for forming an organic light emitting device, comprising:
forming a lower electrode over a substrate;
forming an organic material layer over the lower electrode;
exposing the organic material layer to a light absorbent to form an organic residue region on the organic material layer;
forming an emitting layer over the organic residue region; and
forming an upper electrode over the emitting layer.

2. The method according to claim 1, wherein the organic residue region comprises a carbonyl group, a phenyl group, a —C—O group, an aromatic hydrogen, an alkyl group, an alkyne group, a monofluoromethyl group, a trifluoromethyl group, a —S═O group, a —C—S group, a —CH₃ group, a —O—H group, a —P═O group, an aromatic —C═C group, a —C—O—C group, a —C—F group, a —C—F₃ group, a —C≡C group, a —N—H group, a NO₂ group, a —C═N⁺ group, a —N—O group, a PF₆ group, or a combination thereof.

3. The method according to claim 1, further comprising:
forming a protrusion structure over the substrate and partially covering the lower electrode; and
exposing the protrusion structure to the light absorbent to form the organic residue region further on the protrusion structure.

4. The method according to claim 3, wherein a concentration of the organic residue region on the protrusion structure is different from a concentration of the organic residue region on the organic material layer.

5. The method according to claim 1, further comprising:
forming a buffer layer over the organic material layer;
forming a photoresist structure over the buffer layer, wherein the photoresist structure comprises the light absorbent;
partially removing the buffer layer according to a pattern of the photoresist structure to partially expose the organic material layer over the lower electrode; and
removing the photoresist structure to exposing a portion of the organic material layer to the light absorbent.

6. The method according to claim 5, wherein forming the photoresist structure comprises:
forming a first photoresist layer over the buffer layer; and
forming a second photoresist layer contacting the first photoresist layer, wherein a light transmittance of the first photoresist layer is lower than a light transmittance of the second photoresist layer.

7. The method according to claim 6, wherein the first photoresist layer comprises a first absorbent material of the light absorbent, and the second photoresist layer comprises a second absorbent material of the light absorbent that is different from the first absorbent material.

8. The method according to claim 1, further comprising:
forming an adhesion layer over the organic material layer;
forming a photoresist layer contacting the adhesion layer and defining an exposed portion of the organic material layer, the photoresist layer comprising the light absorbent; and
applying a solution to remove the adhesion layer and the photoresist layer and bring the light absorbent to contact the exposed portion of the organic material layer.

9. The method according to claim 8, wherein the adhesion layer comprises a photoresist material comprising the light absorbent.

10. The method according to claim 1, further comprising:
exposing a circuit structure of the substrate to the light absorbent to form the organic residue region further on the circuit structure.

11. An organic light emitting device, comprising:
a first lower electrode over a substrate;
a first organic light emitting layer over the first lower electrode; and
an organic residue region on at least a portion of the first organic light emitting layer, wherein the organic residue region comprises a carbonyl group, a phenyl group, a —C—O group, an aromatic hydrogen, an alkyl group, an alkyne group, a monofluoromethyl group, a trifluoromethyl group, a —S═O group, a —C—S group, a —CH₃ group, a —O—H group, a —P═O group, an aromatic —C═C group, a —C—O—C group, a —C—F group, a —C—F₃ group, a —C≡C group, a —N—H group, a NO₂ group, a —C═N⁺ group, a —N—O group, a PF₆ group, or a combination thereof.

12. The organic light emitting device according to claim 11, further comprising a protrusion structure over the substrate and partially covering the first lower electrode, wherein the organic residue region is further on the protrusion structure.

13. The organic light emitting device according to claim 11, wherein the substrate comprises a circuit structure spaced apart from the first organic light emitting layer, and the organic residue region is further on the circuit structure.

14. The organic light emitting device according to claim 13, wherein the organic residue region is further on a portion of a surface of the substrate between the circuit structure and the first organic light emitting layer.

15. The organic light emitting device according to claim 11, further comprising:
a second lower electrode over the substrate; and
a second organic light emitting layer over the second lower electrode, wherein the organic residue region is further on a portion of the second organic light emitting layer.

16. An organic light emitting device, comprising:
a first electrode and a second electrode over a top surface of a substrate;
an isolation structure over the substrate and spacing the first electrode apart from the second electrode; and
an organic light emitting layer extending over the first electrode, the second electrode, and the isolation structure,
wherein the isolation structure has a top surface substantially aligned with a top surface of the first electrode, or the isolation structure has a lateral surface inclined at an angle of less than about 80°relative to the top surface of the substrate.

17. The organic light emitting device according to claim 16, wherein the isolation structure comprises a protrusion partially over the first electrode and having the lateral surface.

18. The organic light emitting device according to claim 17, wherein the first electrode comprises a tapered portion that gradually narrows toward an interior of the protrusion.

19. The organic light emitting device according to claim 16, wherein the top surface of the isolation structure, the top surface of the first electrode, and a top surface of the second electrode collectively form a substantially flat surface.

20. The organic light emitting device according to claim 16, wherein the substrate has a cavity between the first electrode and the second electrode and recessed from the top surface of the substrate, and the isolation structure is at least partially within the cavity.
